(19) United States
(12) Patent Application Publication
(10) Pub. No.: US 2025/0324895 A1
(43) Pub. Date: Oct. 16, 2025

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., LTD., Yongin-si (KR)

(72) Inventor: Chun Gi YOU, Yongin-si (KR)

(21) Appl. No.: 19/022,995

(22) Filed: Jan. 15, 2025

(30) Foreign Application Priority Data
Apr. 15, 2024 (KR) 10-2024-0050024

(51) Int. Cl. H10K 59/80; H10K 59/122

(52) U.S. Cl. CPC H10K 59/876; H10K 59/122; H10K 59/80518

(57) ABSTRACT

A display device according to one or more embodiments of the present disclosure includes first to third sub-pixels, wherein each of the first to third sub-pixels includes: a reflective electrode; a resonant layer on the reflective electrode; a first electrode on the resonant layer; a pixel defining layer positioned over the first electrode, the pixel defining layer having an opening; a light emitting structure on the first electrode and the pixel defining layer; and a second electrode on the light emitting structure, wherein a thickness of the resonant layer of the first sub-pixel is smaller than a thickness of the resonant layer of the second sub-pixel, and wherein a depth of the opening of the first sub-pixel is greater than a depth of the opening of the second sub-pixel.

### CROSS-REFERENCE TO RELATED APPLICATION

The present application claims priority to and the benefit of Korean Patent Application No. 10-2024-0050024, filed on Apr. 15, 2024, in the Korean Intellectual Property Office, the entire disclosure of which is incorporated herein by reference.

### BACKGROUND

### 1. Field

Aspects of the present disclosure generally relate to a display device, a method of manufacturing the display device, and an electronic device including the display device.

### 2. Description of the Related Art

Recently, as interest in information displays is increased, research and development of display devices have been continuously conducted.

### SUMMARY

Aspects of embodiments of the present disclosure are directed to a high luminance display device and a method of manufacturing the display device.

According to some embodiments of the present disclosure, there is provided a display device including: first to third sub-pixels, wherein each of the first to third sub-pixels includes: a reflective electrode; a resonant layer on the reflective electrode; a first electrode on the resonant layer; a pixel defining layer positioned over the first electrode, the pixel defining layer having an opening; a light emitting structure on the first electrode and the pixel defining layer; and a second electrode on the light emitting structure, wherein a thickness of the resonant layer of the first sub-pixel is smaller than a thickness of the resonant layer of the second sub-pixel, and wherein a depth of the opening of the first sub-pixel is greater than a depth of the opening of the second sub-pixel.

In some embodiments, the first electrode may cover a top surface and a side surface of the resonant layer.

In some embodiments, the first electrode may be in contact with a side surface of the reflective electrode.

In some embodiments, the thickness of the resonant layer of the second sub-pixel may be smaller than a thickness of the resonant layer of the third sub-pixel.

In some embodiments, the depth of the opening of the second sub-pixel may be greater than a depth of the opening of the third sub-pixel.

In some embodiments, the pixel defining layer may include a first layer on the first electrode and a second layer on the first layer.

In some embodiments, the depth of the opening of the third sub-pixel may be equal to a thickness of the first layer.

In some embodiments, a thickness of the first layer may be smaller than a thickness of the second layer.

In some embodiments, the display device may further include a first barrier layer on the bottom of the reflective electrode.

In some embodiments, the display device may further include a second barrier layer on the top of the reflective electrode.

In some embodiments, a thickness of the second barrier layer may be smaller than a thickness of the first barrier layer.

According to some embodiments of the disclosure, there is provided a method of manufacturing a display device, the method including: forming a reflective electrode in first to third sub-pixels; forming a resonant layer on the reflective electrode; patterning the reflective electrode and the resonant layer; forming a first electrode on the reflective electrode and the resonant layer; forming a pixel defining layer over the first electrode; polishing the pixel defining layer; forming a trench of the pixel defining layer between the first to third sub-pixels; forming an opening exposing the first electrode in the pixel defining layer; and forming a light emitting structure on the first electrode exposed by the opening, wherein the resonant layers of the first to third sub-pixels are formed to have different thicknesses from each other.

In some embodiments, the first electrode may be formed directly on a top surface and a side surface of the resonant layer.

In some embodiments, the first electrode may be formed directly on a side surface of the reflective electrode.

In some embodiments, a thickness of the resonant layer of the first sub-pixel may be formed to be smaller than a thickness of the resonant layer of the second sub-pixel.

In some embodiments, a depth of the opening of the first sub-pixel may be formed to be greater than a depth of the opening of the second sub-pixel.

In some embodiments, a thickness of the resonant layer of the second sub-pixel may be formed to be smaller than a thickness of the resonant layer of the third sub-pixel.

In some embodiments, a depth of the opening of the second sub-pixel is formed to be greater than a depth of the opening of the third sub-pixel.

In some embodiments, the method may further include forming a barrier layer between the reflective electrode and the resonant layer.

In some embodiments, the pixel defining layer may include a first layer and a second layer formed on the first layer, and in the polishing of the pixel defining layer, the second layer may be polished such that a top surface of the first layer of the third sub-pixel is exposed.

According to some embodiments of the present disclosure, there is provided an electronic device including: a processor to provide input image data; and a display device to display an image based on the input image data, the display device including sub-pixel areas, wherein the display device comprises first to third sub-pixels, wherein each of the first to third sub-pixels includes: a reflective electrode; a resonant layer on the reflective electrode; a first electrode on the resonant layer; a pixel defining layer positioned over the first electrode, the pixel defining layer having an opening; a light emitting structure on the first electrode and the pixel defining layer; and a second electrode on the light emitting structure, wherein a thickness of the resonant layer of the first sub-pixel is smaller than a thickness of the resonant layer of the second sub-pixel, and wherein a depth of the opening of the first sub-pixel is greater than a depth of the opening of the second sub-pixel.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating a display device according to some embodiments of the present disclosure.

FIG. 2 is a block diagram illustrating one of the sub-pixels shown in FIG. 1 according to some embodiments of the present disclosure.

FIG. 3 is a circuit diagram illustrating the sub-pixel shown in FIG. 2 according to some embodiments of the present disclosure.

FIG. 4 is a plan view illustrating a display panel shown in FIG. 1 according to some embodiments of the present disclosure.

FIG. 5 is an exploded perspective view illustrating a portion of the display panel shown in FIG. 4 according to some embodiments of the present disclosure.

FIG. 6 is a plan view illustrating one of the pixels shown in FIG. 5 according to some embodiments of the present disclosure.

FIG. 7 illustrates a sectional view taken along the line I-l′ shown in FIG. 6 according to some embodiments of the present disclosure.

FIGS. 8 and 9 are enlarged sectional views illustrating a portion of a light emitting element layer shown in FIG. 7 according to some embodiments of the present disclosure.

FIG. 10 is a sectional view illustrating a light emitting structure included in any one of first to third light emitting elements shown in FIG. 7 according to some embodiments of the present disclosure.

FIG. 11 is a sectional view illustrating the light emitting structure included in the one of the first to third light emitting elements shown in FIG. 7 according to some other embodiments of the present disclosure.

FIG. 12 is a plan view illustrating one of the pixels shown in FIG. 5 according to some other embodiments of the present disclosure.

FIG. 13 is a plan view illustrating one of the pixels shown in FIG. 5 according to still some other embodiments of the present disclosure.

FIG. 14 is a block diagram illustrating a display system according to some embodiments of the present disclosure.

FIG. 15 is a perspective view illustrating an application example of the display system shown in FIG. 14 according to some embodiments of the present disclosure.

FIG. 16 is a view illustrating a head-mounted display device shown in FIG. 14, which is worn by a user, according to some embodiments of the present disclosure.

FIGS. 17 to 24 are sectional views illustrating process steps of a method of manufacturing a display device according to some embodiments of the present disclosure. FIGS. 25 to 34 are sectional views illustrating process steps of a method of manufacturing a display device according to some embodiments of the present disclosure.

### DETAILED DESCRIPTION

Hereinafter, embodiments of the present disclosure will be described in more detail with reference to the accompanying drawings. In the description below, parts necessary to understand an operation according to the present disclosure are described, and the descriptions of other parts may be omitted in order not to unnecessarily obscure subject matters of the present disclosure. In addition, the present disclosure is not limited to exemplary embodiments described herein, but may be embodied in various different forms. Rather, exemplary embodiments described herein are provided to thoroughly and completely describe the disclosed contents and to sufficiently transfer (e.g., convey) the ideas of the disclosure to a person of ordinary skill in the art.

In the entire specification, when an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiment. It will be understood that when a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the present disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of ideal embodiments (and an intermediate structure) of the present disclosure, so that changes in a shape as shown due to, for example, manufacturing technology and/or a tolerance may be expected. Therefore, the embodiments of the present disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

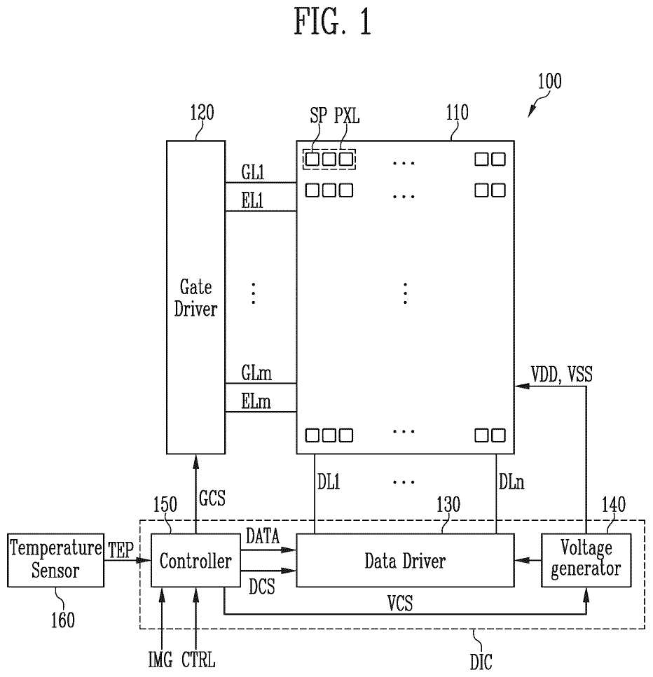

FIG. 1 is a block diagram illustrating a display device according to some embodiments of the present disclosure.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to mth gate lines GL1 to GLm. The sub-pixels SP may be connected to the data driver 130 through first to nth data lines DL1 to DLn.

Each of the sub-pixels SP may include at least one light emitting element configured to generate light. Accordingly, each of the sub-pixels SP may generate light of a specific color, such as red, green, blue, cyan, magenta, or yellow. Two or more sub-pixels among the sub-pixels SP may constitute one pixel PXL. For example, three sub-pixels SP may constitute one pixel PXL as shown in FIG. 1.

The gate driver 120 may be connected to the sub-pixels SP arranged in a row direction through the first to mth gate lines GL1 to GLm. The gate driver 120 may output gate signals to the first to mth gate lines GL1 to GLm in response to a gate control signal GCS. In some embodiments, the gate control signal GCS may include a start signal indicating a start of each frame, a horizontal synchronization signal for outputting gate signals in synchronization with timings at which data signals are applied, and the like.

In some embodiments, first to mth light emitting control lines EL1 to ELm connected to the sub-pixels SP in the row direction may be further provided. The gate driver 120 may include an emission control driver configured to control the first to mth emission control lines EL1 to ELm, and the emission control driver may operate under the control of (e.g., be controlled by) the controller 150.

The gate driver 120 may be disposed at one side of the display panel 110. However, embodiments are not limited thereto. For example, the gate driver 120 may be divided into two or more drivers which are physically and/or logically divided, and these drivers may be disposed at one side of the display panel 110 and the other side of the display panel 110, which is opposite to the one side. As such, in some embodiments, the gate driver 120 may be disposed in various forms at the periphery of the display panel 110.

The data driver 130 may be connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. In some embodiments, the data control signal DCS may include a source start pulse, a source shift clock, a source output enable signal, and/or the like.

The data driver 130 may apply data signals having grayscale voltages corresponding to the image data DATA to the first to nth data lines DL1 to DLn by using voltages from the voltage generator 140. When a gate signal is applied to each of the first to mth gate lines GL1 to GLm, data signals corresponding to the image data DATA may be applied to the data lines DL1 to DLm, respectively. Accordingly, corresponding sub-pixels SP may generate light corresponding to the data signals. Accordingly, an image may be displayed on the display panel 110.

In some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may be configured to generate a plurality of voltages by receiving an input voltage from the outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the voltage level of the first power voltage VDD. In other embodiments, the first power voltage VDD or the second power voltage VSS may be provided by an external device of the display device 100.

In some embodiments, the voltage generator 140 may generate various voltages. For example, the voltage generator 140 may generate an initialization voltage applied to the sub-pixels SP. For example, a set or predetermined reference voltage may be applied to the first to nth data lines DL1 to DLn in a sensing operation for sensing electrical characteristics of transistors and/or light emitting elements of the sub-pixels SP, and the voltage generator 140 may generate the reference voltage.

The controller 150 may control overall operations of the display device 100. The controller 150 may receive, from the outside, input image data IMG and a control signal CTRL for controlling display thereof. The controller 150 may provide the gate control signal GCS, the data control signal DCS, and the voltage control signal VCS in response to the control signal CTRL.

The controller 150 may convert the input image data IMG to be suitable for the display device 100 or the display panel 110, thereby outputting the image data DATA. In some embodiments, the controller 150 may align the input image data IMG to be suitable for the sub-pixels SP in units of rows, thereby outputting the image data DATA.

Two or more components among the data driver 130, the voltage generator 140, and the controller 150 may be mounted on (e.g., connected to or connected in) one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. In other embodiments, at least one of the data driver 130, the voltage generator 140, and the controller 150 may be provided as a component distinguished from (e.g., separated from or external to) the driver integrated circuit DIC.

The display device 100 may include at least one temperature sensor 160. The temperature sensor 160 may be configured to sense a temperature at the periphery thereof and generate temperature data TEP indicating the sensed temperature. In some embodiments, the temperature sensor 160 may be disposed to be adjacent to the display panel 110 and/or the driver integrated circuit DIC.

The controller 150 may control various operations of the display device 100 in response to the temperature data TEP. In some embodiments, the controller 150 may adjust the luminance of an image output from the display device 100 in response to the temperature data TEP. For example, the controller 150 may control components such as the data driver 130 and/or the voltage generator 140, thereby adjusting data signals and the first and second power voltages VDD and VSS.

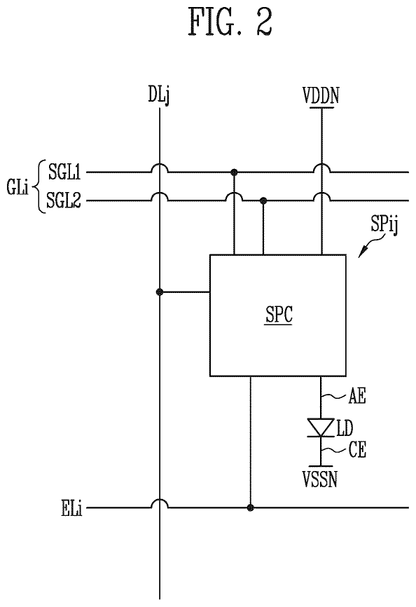

FIG. 2 is a block diagram illustrating any one of the sub-pixels shown in FIG. 1 according to some embodiments of the present disclosure. In FIG. 2, a sub-pixel SPij arranged on an ith row (i is an integer greater than or equal to 1 and smaller than or equal to m) and a jth column (j is an integer greater than or equal to 1 and smaller than or equal to n) among the sub-pixels SP shown in FIG. 1 is illustrated.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be a node transferring the first power voltage VDD shown in FIG. 1, and the second power voltage node VSSN may be a node transferring the second power voltage VSS shown in FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an ith gate line GLi among the first to mth gate lines GL1 to GLm shown in FIG. 1, an ith emission control line ELi among the first to mth emission control lines EL1 to ELm shown in FIG. 1, and a jth data line DLj among the first to nth data lines DL1 to DLn shown in FIG. 1. The sub-pixel circuit SPC may be configured to control the light emitting element LD according to signals received through these signal lines.

The sub-pixel circuit SPC may operate in response to a gate signal received through the ith gate line GLi. The ith gate line GLi may include one or more sub-gate lines. In some embodiments, as shown in FIG. 2, the ith gate line GLi may include first and second sub-gate lines SGL1 and SGL2. The sub-pixel circuit SPC may operate in response to gate signals received through the first and second sub-gate lines SGL1 and SGL2. As such, when the ith gate line GLi includes two or more sub-gate lines, the sub-pixel circuit SPC may operate in response to gate signals received through the corresponding sub-gate lines.

The sub-pixel circuit SPC may operate in response to an emission control signal received through the ith emission control line ELi. In some embodiments, the ith emission control line ELi may include one or more sub-emission control lines. When the ith emission control line ELi includes two or more sub-emission control lines, the sub-pixel circuit SPC may operate in response to emission control signals received through the corresponding emission control lines.

The sub-pixel circuit SPC may receive a data signal through the jth data line DLj. The sub-pixel circuit SPC may store a voltage corresponding to the data signal in response to at least one of the gate signals received through the first and second sub-gate lines SGL1 and SGL2. The sub-pixel circuit SPC may control a current flowing from the first power voltage node VDDN to the second power voltage node VSSN through the light emitting element LD according to the stored voltage in response to the emission control signal received through the ith emission control line ELi. Accordingly, the light emitting element LD may generate light with a luminance corresponding to the data signal.

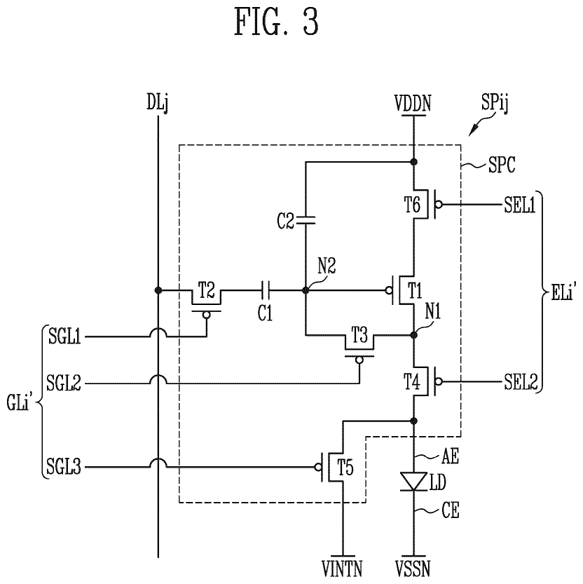

FIG. 3 is a circuit diagram illustrating the sub-pixel shown in FIG. 2 according to some embodiments of the present disclosure.

Referring to FIG. 3, a sub-pixel SPij may include a sub-pixel circuit SPC and a light emitting element LD.

The sub-pixel circuit SPC may be connected to an ith gate line GLi′, an ith emission control line ELi′, and a jth data line DLj. When comparing the ith gate line GLi′ with the ith gate line GLi shown in FIG. 2, the ith gate line GLi′ may further include a third sub-gate line SGL3. When comparing the ith emission control line ELi′ with the ith emission control line ELi shown in FIG. 2, the ith emission control line ELi′ may include a first sub-emission control line SEL1 and a second sub-emission control line SEL2.

The sub-pixel circuit SPC may include first to sixth transistors T1 to T6 and first and second capacitors C1 and C2.

The first transistor T1 may be connected between a first power voltage node VDDN and a first node N1. A gate of the first transistor T1 may be connected to a second node N2, and accordingly, the first transistor T1 may be turned on according to a voltage level of the second node N2. The first transistor T1 may be designated as a driving transistor.

The second transistor T2 may be connected between the jth data line DLj and the second node N2. A gate of the second transistor T2 may be connected to a first sub-gate line SGL1, and accordingly, the second transistor T2 may be turned on in response to a gate signal of the first sub-gate line SGL1. The second transistor T2 may be designated as a switching transistor.

The third transistor T3 may be connected between the first node N1 and the second node N2. A gate of the third transistor T3 may be connected to a second sub-gate line SGL2, and accordingly, the third transistor T3 may be turned on in response to a gate signal of the second sub-gate line SGL2.

The fourth transistor T4 may be connected between the first node N1 and an anode electrode AE of the light emitting element LD. A gate of the fourth transistor T4 may be connected to the second sub-emission control line SEL2, and accordingly, the fourth transistor T4 may be turned on in response to an emission control signal of the second sub-emission control line SEL2.

The fifth transistor T5 may be connected between the anode electrode AE of the light emitting element LD and an initialization voltage node VINTN. The initialization voltage node VINTN may be configured to transfer an initialization voltage.

In some embodiments, the initialization voltage may be provided by the voltage generator 140 shown in FIG. 1. In other embodiments, the initialization voltage may be provided by an external device of the display device 100. A gate of the fifth transistor T5 may be connected to the third sub-gate line SGL3, and accordingly, the fifth transistor T5 may be turned on in response to a gate signal of the third sub-gate line SGL3.

The sixth transistor T6 may be connected between the first power voltage node VDDN and the first transistor T1. A gate of the sixth transistor T6 may be connected to the first sub-emission control line SEL1, and accordingly, the sixth transistor T6 may be turned on in response to an emission control signal of the first sub-emission control line SEL1.

The first capacitor C1 may be connected between the second transistor T2 and the second node N2. The second capacitor C2 may be connected between the first power voltage node VDDN and the second node N2.

As such, the sub-pixel circuit SPC may include the first to sixth transistors T1 to T6 and the first and second capacitors C1 and C2. However, embodiments are not limited thereto. The sub-pixel circuit SPC may be implemented as any one of various types of circuits each including a plurality of transistors and one or more capacitors. For example, the sub-pixel circuit SPC may include two transistors and one capacitor. In accordance with embodiments of the sub-pixel circuit SPC, the number of sub-gate lines included in the ith gate line GLi′ and the number of sub-emission control lines included in the ith emission control line ELi′ may vary.

The first to sixth transistors T1 to T6 may be P-type transistors. Each of the first to sixth transistors T1 to T6 may be a Metal Oxide Silicon Field Effect Transistor (MOSFET). However, embodiments are not limited thereto. For example, at least one of the first to sixth transistors T1 to T6 may be replaced with an N-type transistor.

In some embodiments, the first to sixth transistors T1 to T6 may include an amorphous silicon semiconductor, a monocrystalline silicon semiconductor, a polycrystalline silicon semiconductor, an oxide semiconductor, and/or the like.

The light emitting element LD may include the anode electrode AE, a cathode electrode CE, and a light emitting layer. The light emitting layer may be disposed between the anode electrode AE and the cathode electrode CE. After a data signal transferred through the jth data line DLj is reflected on a voltage of the second node N2, the fourth and sixth transistors T4 and T6 may be turned on when the emission control signals of the first and second sub-emission control lines SEL1 and SEL2 are enabled to a low level. The first transistor T1 may be turned on according to the voltage of the second node N2, and accordingly, a current may flow from the first power voltage node VDDN to a second power voltage node VSSN. The light emitting element LD may emit light according to an amount of the current flowing from the first power voltage node VDDN to the second power voltage node VSSN.

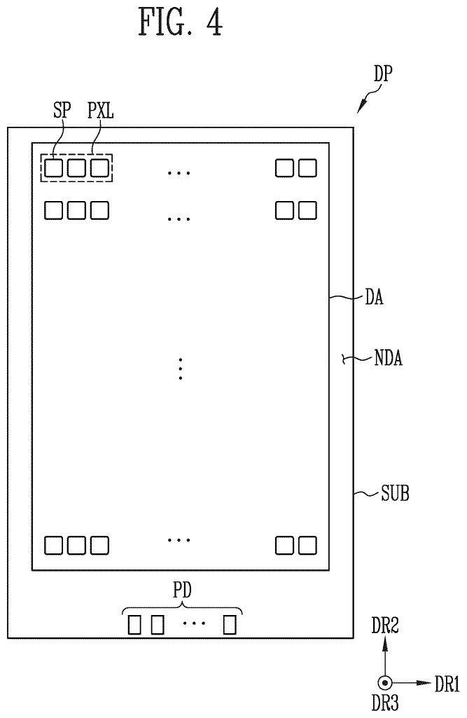

FIG. 4 is a plan view illustrating the display panel shown in FIG. 1 according to some embodiments of the present disclosure.

Referring to FIG. 4, an embodiment DP of the display panel 110 shown in FIG. 1 may include a display area DA and a non-display area NDA. The display panel DP may display an image through the display area DA. The non-display area NDA may be disposed at the periphery of the display area DA.

The display panel DP may include a substrate SUB, sub-pixels SP, and pads PD. When the display panel DP is used as a display screen of a Head Mounted Display (HMD), a Virtual Reality (VR) device, a Mixed Reality (MR) device, an Augmented Reality (AR) device, and the like, the display panel DP may be located very close to eyes of a user. The sub-pixels SP having a relatively high degree of integration may be required. In order to increase the degree of integration of the sub-pixels SP, the substrate SUB may be provided as a silicon substrate. The sub-pixels SP and/or the display panel DP may be formed on the substrate SUB as the silicon substrate. The display device 100 (see FIG. 1) including the display panel DP formed on the substrate SUB as the silicon substrate may be designated as an OLED on Silicon (OLEDoS) display device.

The sub-pixels SP may be disposed in the display area DA on the substrate SUB. The sub-pixels SP may be arranged in a matrix form along a first direction DR1 and a second direction DR2 intersecting the first direction DR1. However, embodiments are not limited thereto. For example, the sub-pixels SP may be arranged in a zigzag form along the first direction DR1 and the second direction DR2. For example, the sub-pixels SP may be disposed in a PENTILE® (Trademark of Samsung Display Co., Ltd.) form. For example, the subpixels SP may be arranged in a RGBG matrix structure. The first direction DR1 may be a row direction, and the second direction DR2 may be a column direction.

Two or more sub-pixels among the sub-pixels SP may constitute one pixel PXL.

A component for controlling the sub-pixels SP may be disposed in the non-display area NDA on the substrate SUB. For example, lines connected to the sub-pixels SP, such as the first to mth gate lines GL1 to GLm and the first to nth data lines DL1 to DLn, which are shown in FIG. 1, may be disposed in the non-display area NDA.

At least one of the gate driver 120, the data driver 130, the voltage generator 140, the controller 150, and the temperature sensor 160, which are shown in FIG. 1, may be integrated in the non-display area NDA of the display panel DP. In some embodiments, the gate driver 120 shown in FIG. 1 is mounted on the display panel DP, and may be disposed in the non-display area NDA. In other embodiments, the gate driver 120 may be implemented as an integrated circuit distinguished from the display panel DP. In some embodiments, the temperature sensor 160 may be disposed in the non-display area NDA to sense a temperature of the display panel DP.

The pads PD may be disposed in the non-display area NDA on the substrate SUB. The pads PD may be electrically connected to the sub-pixels SP through the lines. For example, the pads PD may be connected to the sub-pixels SP through the first to nth data lines DL1 to DLn.

The pads PD may interface the display panel DP with other components of the display device 100 (see FIG. 1). In some embodiments, voltages and signals, which are utilized for operations of components included in the display panel DP, may be provided from the driver integrated circuit DIC shown in FIG. 1 through the pads PD. For example, the first to nth data lines DL1 to DLn may be connected to the driver integrated circuit DIC through the pads PD. For example, the first and second power voltages VDD and VSS may be received from the driver integrated circuit DIC through the pads PD. When the gate driver 120 is mounted in the display panel DP, the gate control signal GCS may be transmitted from the driver integrated circuit DIC to the gate driver 120 through the pads PD.

In some embodiments, a circuit board may be electrically connected to the pads PD, using a conductive adhesive member, such as an anisotropic conductive film. The circuit board may be a Flexible Printed Circuit Board (FPCB) or a flexible film, which has a flexible material. The driver integrated circuit DIC may be mounted on the circuit board to be electrically connected to the pads PD.

In some embodiments, the display area DA may have various suitable shapes. The display area DA may have a closed-loop shape including linear sides and/or curved sides. For example, the display area DA may have shapes such as a polygon, a circle, a semicircle, and an ellipse.

In some embodiments, the display panel DP may have a flat display surface. In other embodiments, the display panel DP may at least partially have a round display surface. In some embodiments, the display panel DP may be bendable, foldable, and/or rollable. The display panel DP and/or the substrate SUB may include materials having flexibility.

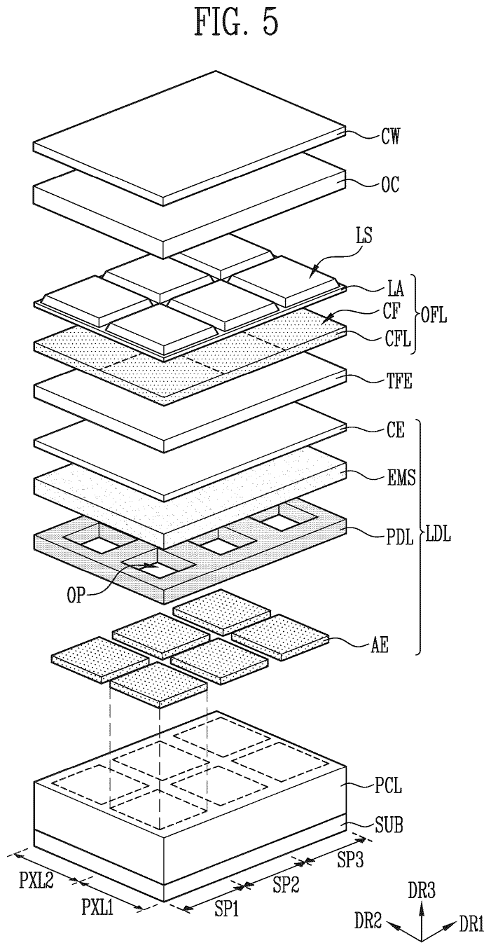

FIG. 5 is an exploded perspective view illustrating a portion of the display panel shown in FIG. 4 according to some embodiments of the present disclosure. In FIG. 5, for clear and brief description, a portion of the display panel DP, which corresponds to two pixels PXL1 and PXL2 among the pixels PXL shown in FIG. 4, may be schematically illustrated. A portion of the display panel DP, which corresponds to the other pixels, may also be configured identically.

Referring to FIGS. 4 and 5, each of first and second pixels PXL1 and PXL2 may include first to third sub-pixels SP1, SP2, and SP3. However, embodiments are not limited thereto. For example, each of the first and second pixels PXL1 and PXL2 may include four sub-pixels or include two sub-pixels.

In FIG. 5, it may be illustrated that the first to third sub-pixels SP1, SP2, and SP3 may have quadrangular shapes when viewed in a third direction DR3 intersecting the first and second directions DR1 and DR2 (e.g., in a plan view), and have the same or substantially the same size. However, embodiments are not limited thereto. The first to third sub-pixels SP1, SP2, and SP3 may be modified to have various shapes.

The display panel DP may include a substrate SUB, a pixel circuit layer PCL, a light emitting element layer LDL, an encapsulation layer TFE, an optical functional layer OFL, an overcoat layer OC, and a cover window CW.

In some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a Silicon On Insulator (SOI) layer, a Semiconductor On Insulator (SeOI) layer, or the like. In other embodiments, the substrate SUB may include a glass substrate. In still other embodiments, the substrate SUB may include a polyimide (PI) substrate.

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may serve as at least some of circuit elements, lines, and the like. The conductive patterns may include copper, but embodiments are not limited thereto.

The circuit elements may include a sub-pixel circuit SPC (see FIG. 2) of each of the first to third sub-pixels SP1 to SP3. The sub-pixel circuit SPC may include transistors and one or more capacitors. Each transistor may include a semiconductor portion including a source region, a drain region, and a channel region, and a gate electrode overlapping with the semiconductor portion. In some embodiments, when the substrate SUB is provided as a silicon substrate, the semiconductor portion may be included in the substrate SUB, and the gate electrode may be included as a conductive pattern of the pixel circuit layer PCL in the pixel circuit layer PCL. In some embodiments, when the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, the capacitor may include electrodes spaced apart from each other in the third direction DR3 with an insulating layer interposed therebetween.

The lines of the pixel circuit layer PCL may include signal lines, e.g., a gate line, an emission control line, a data line, and the like, which are connected to each of the first to third sub-pixels SP1, SP2, and SP3. The lines may further include a line connected to the first power voltage node VDDN shown in FIG. 2. The lines may further include a line connected to the second power voltage node VSSN shown in FIG. 2.

The light emitting element layer LDL may include anode electrodes AE, a pixel defining layer PDL, a light emitting structure EMS, and a cathode electrode CE. The anode electrodes AE may be disposed on the pixel circuit layer PCL.

The anode electrodes AE may be in contact with the circuit elements of the pixel circuit layer PCL. The anode electrodes AE may include an opaque conductive material capable of reflecting light, but embodiments are not limited thereto.

The pixel defining layer PDL may be disposed over the anode electrodes AE. The pixel defining layer PDL may include an opening OP exposing a portion of each of the anode electrodes AE. The opening OP of the pixel defining layer PDL may be understood as an emission area corresponding to each of the first to third sub-pixels SP1, SP2, and SP3.

In some embodiments, the pixel defining layer PDL may include an inorganic material. The pixel defining layer PDL may include a plurality of stacked inorganic layers. For example, the pixel defining layer PDL may include silicon oxide (SiOₓ) and silicon nitride (SiNₓ). In other embodiments, the pixel defining layer PDL may include an organic material. However, the material of the pixel defining layer PDL is not limited thereto.

The light emitting structure EMS may be disposed on the anode electrodes AE exposed by the openings OP of the pixel defining layer PDL. The light emitting structure EMS may include a light emitting layer configured to generate light, an electron transport layer configured to transport electrons, a hole transport layer configured to transport holes, and the like.

In some embodiments, the light emitting structure EMS fills the opening OP of the pixel defining layer PDL, and may be entirely disposed on the top of (e.g., entirely cover) the pixel defining layer PDL. In other words, the light emitting structure EMS may extend throughout the first to third sub-pixels SP1, SP2, and SP3. At least some of the layers in the light emitting structure EMS may be cut or bent at boundaries between the first to third sub-pixels SP1, SP2, and SP3. However, embodiments are not limited thereto. For example, portions of the light emitting structure EMS, which correspond to the first to third sub-pixels SP1, SP2, and SP3, may be separated from each other, and each of the portions may be disposed in the opening OP of the pixel defining layer PDL.

The cathode electrode CE may be disposed on the light emitting structure EMS. The cathode electrode CE may extend throughout the first to third sub-pixels SP1, SP2, and SP3. As such, the cathode electrode CE may be provided as a common electrode for the first to third sub-pixels SP1, SP2, and SP3.

The cathode electrode CE may be a thin metal layer having a thickness to a degree to which light emitted from the light emitting structure EMS can be transmitted therethrough. The cathode electrode CE may be formed of a metal material to have a relatively thin thickness or be formed of a transparent conductive material. In some embodiments, the cathode electrode CE may include at least one of various transparent conductive materials including indium tin oxide, indium zinc oxide, indium tin zinc oxide, aluminum zinc oxide, gallium zinc oxide, zinc tin oxide, and gallium tin oxide. In other embodiments, the cathode electrode CE may include at least one of silver (Ag), magnesium (Mg), and mixtures thereof. However, the material of the cathode electrode CE is not limited thereto.

It may be understood that any one of the anode electrodes AE, a portion of the light emitting structure EMS, which overlaps therewith, and a portion of the cathode electrode CE, which overlaps therewith, constitute one light emitting element LD (see FIG. 2). In other words, each of light emitting elements of the first to third sub-pixels SP1, SP2, and SP3 may include one anode electrode AE, a portion of the light emitting structure EMS, which overlaps therewith, and a portion of the cathode electrode CE, which overlaps therewith. In each of the first to third sub-pixels SP1, SP2, and SP3, holes injected from the anode electrode AE and electrons injected from the cathode electrode CE may be transported into a light emitting layer of the light emitting structure EMS to form excitons, and light may be generated when the excitons are changed from an excited state to a ground state. A luminance of the light may be determined according to an amount of current flowing through the light emitting layer. A wavelength band of the generated light may be determined according to a configuration of the light emitting layer.

The encapsulation layer TFE may be disposed over the cathode electrode CE. The encapsulation layer TFE may cover the light emitting element layer LDL and/or the pixel circuit layer PCL. The encapsulation layer TFE may be configured to prevent oxygen and/or moisture from infiltrating into the light emitting element layer LDL. In some embodiments, the encapsulation layer TFE may include a structure in which at least one inorganic layer and at least one organic layer are alternately stacked. For example, the inorganic layer may include silicon nitride, silicon oxide, silicon oxynitride (SiOₓN_{y}), or the like. For example, the organic layer may include an organic insulating material such as acrylic resin, epoxy resin, phenolic resin, polyamide resin, polyimide resin, unsaturated polyester resin, polyphenylene resin, polyphenylenesulfide resin, or benzocyclobutene (BCB). However, the materials of the organic layer and the inorganic layer of the encapsulation layer TFE are not limited thereto.

In order to improve encapsulation efficiency of the encapsulation layer TFE, the encapsulation layer TFE may further include a thin film including aluminum oxide (AlOₓ). The thin film including the aluminum oxide may be located on a top surface of the encapsulation layer TFE, which faces the optical functional layer OFL, and/or a bottom surface of the encapsulation layer TFE, which faces the light emitting element layer LDL.

The thin film including the aluminum oxide may be formed through an Atomic Layer Deposition (ALD) process. However, embodiments are not limited thereto. The encapsulation layer TFE may further include a thin film formed of at least one of various materials suitable for the improvement of the encapsulation efficiency.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may be configured to filter light emitted from the light emitting structure EMS, thereby selectively outputting light of a wavelength band or a color, which corresponds to each sub-pixel SP. The color filter layer CFL may include color filters CF respectively corresponding to the first to third sub-pixels SP1, SP2, and SP3. Each of the color filters CF may allow light having a wavelength band corresponding to a corresponding sub-pixel to pass therethrough.

For example, a color filter corresponding to the first sub-pixel SP1 may allow light of a red color to pass therethrough, a color filter corresponding to the second sub-pixel SP2 may allow light of a green color to pass therethrough, and a color filter corresponding to the third sub-pixel SP3 may allow light of a blue color to pass therethrough. According to light emitted from the light emitting structure EMS in each sub-pixel SP, at least some of the color filters CF may be omitted.

The lens array LA may be disposed on the color filter layer CFL. The lens array LA may include lenses LS respectively corresponding to the first to third sub-pixels SP1, SP2, and SP3. Each of the lenses LS may output light emitted from the light emitting structure EMS along an intended path, thereby improving light emission efficiency. The lens array LA may have a relatively high refractive index. For example, the lens array LA may have a refractive index higher than a refractive index of the overcoat layer OC. In some embodiments, the lenses LS may include an organic material. In some embodiments, the lenses LS may include an acryl-based material. However, the material of the lenses LS is not limited thereto.

In some embodiments, as compared with the opening OP of the pixel defining layer PDL, at least some of the color filters CF of the color filter layer CFL and at least some of the lenses LS of the lens array LS may be shifted in a direction parallel to a plane defined by the first and second directions DR1 and DR2. For example, in a central area of the display area DA, the center of a color filter and the center of a lens may be aligned or overlap with the center of a corresponding opening OP of the pixel defining layer PDL. For example, in the central area of the display area DA, the opening OP of the pixel defining layer PDL may completely overlap with the corresponding color filter of the color filter layer CFL and the corresponding lens of the lens array LA. In an area of the display area DA, which is adjacent to the non-display area NDA, the center of a color filter and the center of a lens may be shifted in a planar direction from the center of an opening OP of the pixel defining layer PDL. For example, in the area of the display area DA, which is adjacent to the non-display area NDA, the opening OP of the pixel defining layer PDL may partially overlap with the corresponding color filter of the color filter layer CFL and the corresponding lens of the lens array LA. Accordingly, in the center of the display area DA, light emitted from the light emitting structure EMS can be effectively output in a normal direction of the display surface. At an outer portion of the display area DA, light emitted from the light emitting structure EMS can be effectively output in a direction inclined by a set or predetermined angle with respect to the normal direction of the display surface.

The overcoat layer OC may be disposed over the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting lower layers thereof from foreign matters such as dust and moisture. For example, the overcoat layer OC may include at least one of an inorganic insulating layer and an organic insulating layer. For example, the overcoat layer OC may include epoxy, but embodiments are not limited thereto. The overcoat layer OC may have a refractive index lower than a refractive index of the lens array LA.

The cover window CW may be disposed on the overcoat layer OC. The cover window CW may be configured to protect lower layers thereof. The cover window CW may have a refractive index higher than the refractive index of the overcoat layer OC. The cover window CW may include glass, but embodiments are not limited thereto. For example, the cover window CW may be an encapsulation glass configured to protect components disposed thereunder. In other embodiments, the cover window CW may be omitted.

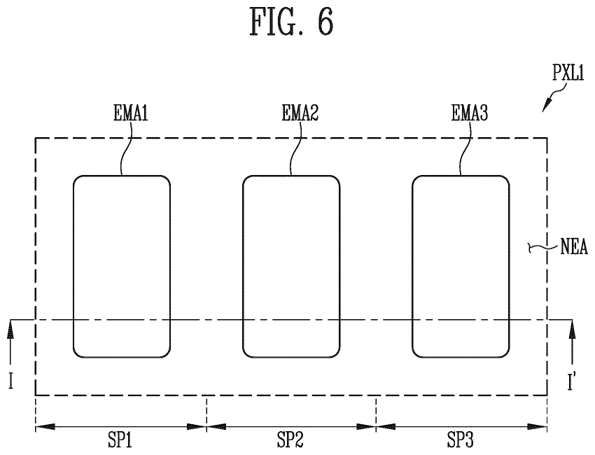

FIG. 6 is a plan view illustrating one of pixels shown in FIG. 5 according to some embodiments of the present disclosure. In FIG. 6, for clear and brief description, the first pixel PXL1 among the first and second pixels PXL1 and PXL2 shown in FIG. 5 is schematically illustrated. The other pixels may be configured identically to the first pixel PXL1.

Referring to FIGS. 5 and 6, the first pixel PXL1 may include first to third sub-pixels SP1, SP2, and SP3 arranged in the first direction DR1.

The first sub-pixel SP1 may include a first emission area EMA1 and a non-emission area NEA at the periphery of (e.g., around or surrounding) the first emission area EMA1. The second sub-pixel SP2 may include a second emission area EMA2 and the non-emission area NEA at the periphery of the second emission area EMA2. The third sub-pixel SP3 may include a third emission area EMA3 and the non-emission area NEA at the periphery of the third emission area EMA3.

The first emission area EMA1 may be an area in which light is emitted from a portion of the light emitting structure EMS (see FIG. 5), which corresponds to the first sub-pixel SP1. The second emission area EMA2 may be an area in which light is emitted from a portion of the light emitting structure EMS, which corresponds to the second sub-pixel SP2. The third emission area EMA3 may be an area in which light is emitted from a portion of the light emitting structure EMS, which corresponds to the third sub-pixel SP3. As described with reference to FIG. 5, the first to third emission areas EMA1, EMA2, and EMA3 may be understood as openings OP of the pixel defining layer PDL, which respectively correspond to the first to third sub-pixels SP1, SP2, and SP3.

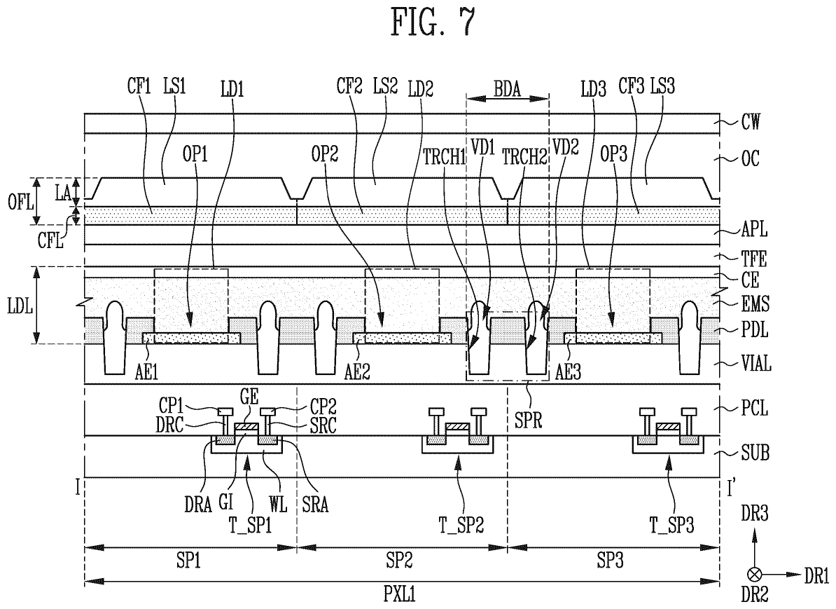

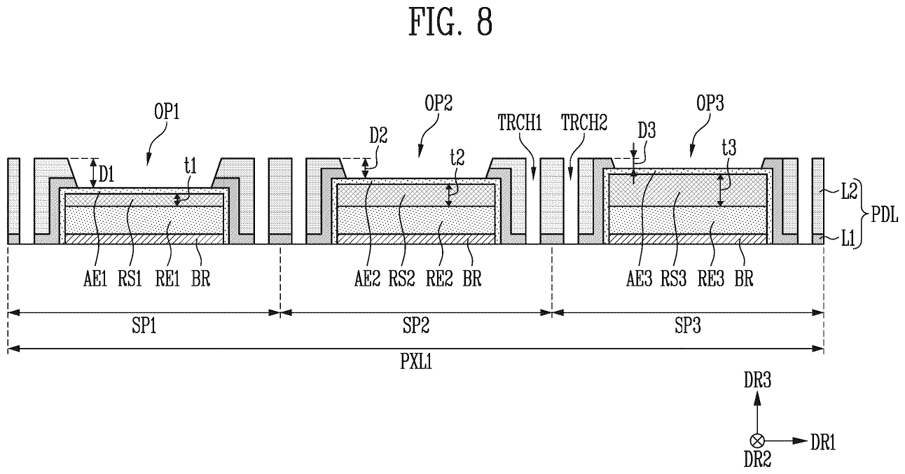

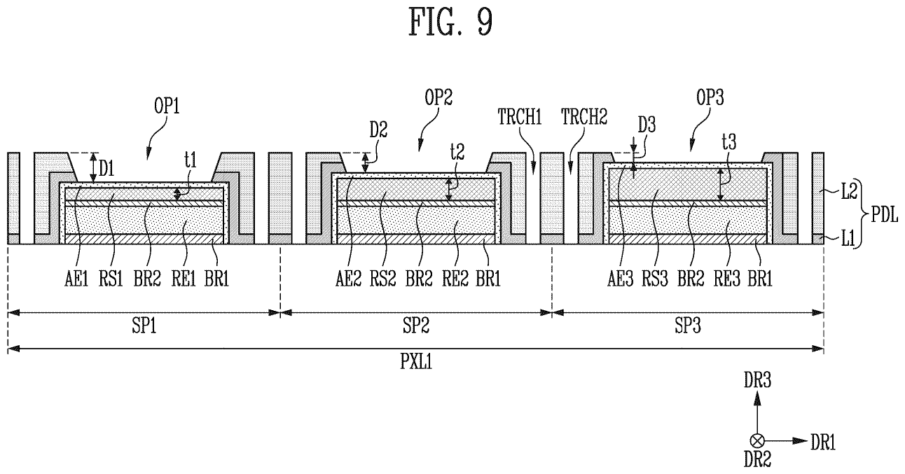

FIG. 7 is a sectional view taken along line I-I′ shown in FIG. 6 according to some embodiments of the present disclosure. FIGS. 8 and 9 are enlarged sectional views illustrating a portion of a light emitting element layer shown in FIG. 7 according to some embodiments of the present disclosure.

Referring to FIGS. 7 to 9, a substrate SUB and a pixel circuit layer PCL disposed on the substrate SUB may be provided.

The substrate SUB may include a silicon wafer substrate formed using a semiconductor process. For example, the substrate SUB may include silicon, germanium, and/or silicon-germanium.

The pixel circuit layer PCL may be disposed on the substrate SUB. The substrate SUB and the pixel circuit layer PCL may include circuit elements of each of first to third sub-pixels SP1, SP2, and SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any one of transistors included in a sub-pixel circuit SPC (see FIG. 2) of the first sub-pixel SP1, the transistor T_SP2 of the second sub-pixel SP2 may be any one of transistors included in a sub-pixel circuit SPC of the second sub-pixel SP2, and the transistor T_SP3 of the third sub-pixel SP3 may be any one of transistors included in a sub-pixel circuit SPC of the third sub-pixel SP3. In FIG. 7, for clear and brief description, one of the transistors of each sub-pixel is illustrated, and the other circuit elements are omitted.

The transistors T_SP1 of the first sub-pixel SP1 may include a source region SRA, a drain region DRA, and a gate electrode GE.

The source region SRA and the drain region DRA may be disposed in the substrate SUB. A well WL formed through an ion implantation process may be disposed in the substrate SUB, and the source region SRA and the drain region DRA may be disposed in the well WL to be spaced apart from each other. A region between the source region SRA and the drain region DRA in the well WL may be defined as a channel region.

The gate electrode GE may overlap with the channel region between the source region SRA and the drain region DRA, and be disposed in the pixel circuit layer PCL. The gate electrode GE may be spaced apart from the well WL or the channel region by an insulating material such as a gate insulating layer GI. The gate electrode GE may include a conductive material.

A plurality of layers included in the pixel circuit layer PCL may include insulating layers and conductive patterns disposed between the insulating layers, and the conductive patterns may include first and second conductive patterns CP1 and CP2. The first conductive pattern CP1 may be electrically connected to the drain region DRA through a drain connection portion DRC penetrating one or more insulating layers. The second conductive pattern CP2 may be electrically connected to the source region SRA through a source connection portion SRC penetrating one or more insulating layers.

As the gate electrode GE and the first and second conductive patterns CP1 and CP2 are connected to other circuit elements and/or lines, the transistor T_SP1 of the first sub-pixel SP1 may be provided as any one of the transistors of the first sub-pixel SP1.

Each of the transistor T_SP2 of the second sub-pixel SP2 and the transistor T_SP3 of the third sub-pixel SP3 may be configured identically to the transistor T_SP1 of the first sub-pixel SP1.

As such, the substrate SUB and/or the pixel circuit layer PCL may include circuit elements of each of the first to third sub-pixels SP1, SP2, and SP3.

A via layer VIAL may be disposed on the pixel circuit layer PCL. The via layer VIAL covers the pixel circuit layer PCL, and may have an entirely flat surface. The via layer VIAL may be configured to planarize step differences on the pixel circuit layer PCL. The via layer VIAL may include at least one of silicon oxide (SiOₓ), silicon nitride (SiNₓ), and silicon carbon nitride (SiCN), but embodiments are not limited thereto.

Referring to FIGS. 7 to 9, a light emitting element layer LDL may be disposed on the via layer VIAL. The light emitting element layer LDL may include barrier layers BR, BR1, and BR2, first to third reflective electrodes RE1, RE2, and RE3, first to third resonant layers RS1, RS2, and RS3, first to third anode electrodes AE1 to AE3, a pixel defining layer PDL, a light emitting structure EMS, and/or a cathode electrode CE.

Referring to FIG. 8, barrier layers BR may be disposed in the first to third sub-pixels SP1, SP2, and SP3, respectively. The barrier layers BR may be disposed on the via layer VIAL. The barrier layers BR may improve electrical connection characteristics between the first to third reflective electrodes RE1, RE2, and RE3 and a circuit element of the pixel circuit layer PCL. In some embodiments, the barrier layers BR may have a multi-layer structure. The multi-layer structure of the barrier layers BR may include titanium (Ti), titanium nitride (TiN), tantalum nitride (TaN), and the like, but the present disclosure is not necessarily limited thereto. The barrier layer BR of each of the first to third sub-pixels SP1, SP2, and SP3 may be in contact with the circuit element disposed in the pixel circuit layer PCL through a via penetrating the via layer VIAL.

Referring to FIG. 9, first barrier layers BR1 may be disposed on the bottom of the first to third reflective electrodes RE1, RE2, and RE3, and second barrier layers BR2 may be disposed on the top of the first to third reflective electrodes RE1, RE2, and RE3. A thickness of each of the first barrier layers BR1 in the third direction DR3 may be greater than a thickness of each of the second barrier layers BR2 in the third direction DR3, however the present disclosure is not limited thereto. In some embodiments, the first barrier layers BR1 and/or the second barrier layers BR2 may have a multi-layer structure. The multi-layer structure of the first barrier layers BR1 and/or the second barrier layers BR2 may include titanium (Ti), titanium nitride (TiN), tantalum nitride (TaN), and the like, but the present disclosure is not necessarily limited thereto.

The first to third reflective electrodes RE1, RE2, and RE3 may be disposed on the barrier layers BR or the first barrier layers BR1. The first to third reflective electrodes RE1, RE2, and RE3 may be disposed in the first to third sub-pixels SP1, SP2, and SP3, respectively.

The first to third reflective electrodes RE1, RE2, and RE3 may serve as full mirrors which reflect light emitted from the light emitting structure EMS toward a display surface (or a cover window CW). The first to third reflective electrodes RE1, RE2, and RE3 may include a metal material suitable for reflecting light. The first to third reflective electrodes RE1, RE2, and RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom, but embodiments are not limited thereto.

The first to third resonant layers RS1, RS2, and RS3 may be disposed on the first to third reflective electrodes RE1, RE2, and RE3 or the second barrier layers BR2. The first to third resonant layers RS1, RS2, and RS3 may be disposed in the first to third sub-pixels SP1, SP2, and SP3, respectively.

The first to third resonant layers RS1, RS2, and RS3 may include an inorganic material such as silicon oxide (SiOₓ), but the present disclosure is not necessarily limited thereto. The first to third resonant layers RS1, RS2, and RS3 may function to adjust a resonance distance such that light can be output in an optimum resonance condition in the first to third sub-pixels SP1, SP2, and SP3. For example, the first to third reflective electrodes RE1, RE2, and RE3 may serve as full mirrors, and the cathode electrode CE may serve as a half mirror. Light emitted from a light emitting layer of the light emitting structure EMS may be amplified by at least partially reciprocating between each of the first to third reflective electrodes RE1, RE2, and RE3 and the cathode electrode CE, and the amplified light may be output through the cathode electrode CE. As such, a distance between each of the first to third reflective electrodes RE1, RE2, and RE3 and the cathode electrode CE may be understood as a resonance distance of light emitted from the light emitting layer of the corresponding light emitting structure EMS.

In some embodiments, thicknesses t1, t2, and t3 of the first to third resonant layers RS1, RS2, and RS3 in the third direction DR3 may be different from one another. For example, a thickness t1 of the first resonant layer RS1 in the third direction DR3 may be smaller than a thickness t2 of the second resonance layer RS2 in the third direction DR3. Accordingly, the first sub-pixel SP1 may have a resonance distance shorter than a resonance distance of the second sub-pixel SP2. The thickness t2 of the second resonant layer RS2 in the third direction DR3 may be smaller than a thickness t3 of the third resonant layer RS3 in the third direction DR3.

Accordingly, the second sub-pixel SP2 may have a resonance distance shorter than a resonance distance of the third sub-pixel SP3. Such an adjusted resonance distance enables light in a specific wavelength range to be effectively and efficiently amplified in each of the first to third sub-pixels SP1, SP2, and SP3. Accordingly, because each of the first to third sub-pixels SP1, SP2, and SP3 can effectively and efficiently output light in a corresponding wavelength band, the luminance of the display device can be improved.

The first to third anode electrodes AE1, AE2, and AE3 may be disposed on the first to third resonant layers RS1, RS2, and RS3, respectively. The first to third anode electrodes AE1, AE2, and AE3 may be disposed in the first to third sub-pixels SP1, SP2, and SP3, respectively.

The first to third anode electrodes AE1, AE2, and AE3 may have shapes similar to shapes of the first to third emission areas EMA1, EMA2, and EMA3 shown in FIG. 6 when viewed in the third direction DR3. The first to third anode electrodes AE1, AE2, and AE3 may be electrically connected to the first to third reflective electrodes RE1, RE2, and RE3, respectively. For example, the first to third anode electrodes

AE1, AE2, and AE3 may cover top surfaces and side surfaces of the first to third resonant layers RS1, RS2, and RS3, respectively, and cover sides of the first to third reflective electrodes RE1, RE2, and RE3 disposed under the first to third resonant layers RS1, RS2, and RS3, respectively. The first to third anode electrodes AE1, AE2, and AE3 may be disposed directly on the top surfaces and the side surfaces of the first to third resonant layers RS1, RS2, and RS3, to be in contact with the top surfaces and the side surfaces of the first to third resonant layers RS1, RS2, and RS3, respectively. The first to third anode electrodes AE1, AE2, and AE3 may be disposed directly on the side surfaces of the first to third reflective electrodes RE1, RE2, and RE3, to be in contact with the side surfaces of the first to third reflective electrodes RE1, RE2, and RE3, respectively.

In some embodiments, the first to third anode electrodes AE1, AE2, and AE3 may include at least one of transparent conductive materials such as indium tin oxide (ITO), indium zinc oxide (IZO), zinc oxide (ZnO), indium gallium zinc oxide (IGZO), and indium tin zinc oxide (ITZO). However, the material of the first to third anode electrodes AE1, AE2, and AE3 is not limited thereto. For example, the first to third anode electrodes AE1, AE2, and AE3 may include titanium nitride.

The pixel defining layer PDL may be disposed over the first to third anode electrodes AE1, AE2, and AE3. The pixel defining layer PDL may include first to third openings OP1, OP2, and OP3 respectively exposing portions of the first to third anode electrodes AE1, AE2, and AE3. The first to third openings OP1, OP2, and OP3 of the pixel defining layer PDL may define emission areas of the first to third sub-pixels SP1, SP2, and SP3, respectively. As such, the pixel defining layer PDL may be disposed in the non-emission area NEA shown in FIG. 6 to define the first to third emission areas EMA1, EMA2, and EMA3 shown in FIG. 6.

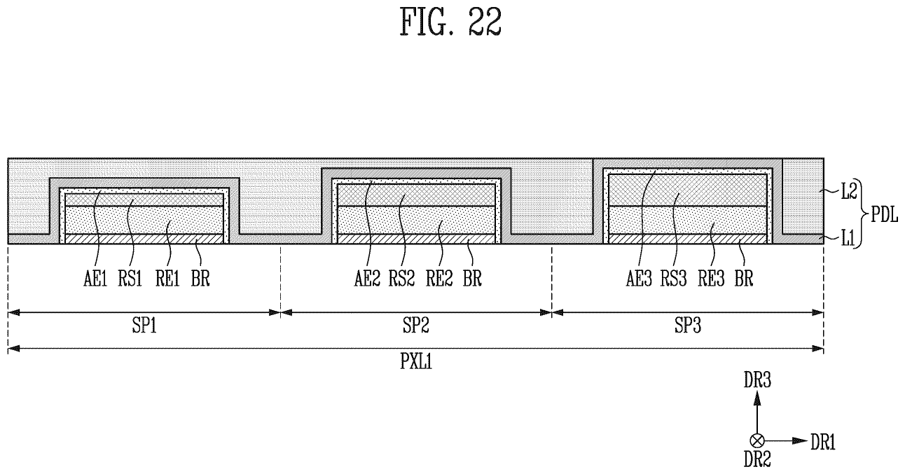

In some embodiments, the pixel defining layer PDL may include a plurality of inorganic insulating layers. For example, the pixel defining layer PDL may include a first layer L1 disposed on the anode electrodes AE1, AE2, and AE3 and a second layer L2 disposed on the first layer L1. A thickness of the first layer L1 in the third direction DR3 may be different from a thickness of the second layer L2 in the third direction DR3. For example, the thickness of the first layer L1 in the third direction DR3 may be smaller than the thickness of the second layer L2 in the third direction DR3. The first layer L1 and/or the second layer L2 may include at least one of silicon oxide (SiOₓ) and silicon nitride (SiNₓ). In an example, the first layer L1 may be formed of silicon nitride (SiNₓ), and the second layer L2 may be formed of silicon oxide (SiOₓ). However, the present disclosure is not necessarily limited thereto. The first layer L1 may serve as an etch stopper in a process of polishing the pixel defining layer PDL. This will be described later with reference to FIG. 22.

The first to third openings OP1, OP2, and OP3 of the pixel defining layer PDL may have different depths due to thickness differences of the first to third resonant layers RS1, RS2, and RS3. For example, when the thickness t1 of the first resonant layer RS1 in the third direction DR3 is formed to be smaller than the thickness t2 of the second resonant layer RS2 in the third direction DR3, a depth D1 of the first opening OP1 in the third direction DR3 may be greater than a depth D2 of the second opening OP2 in the third direction DR3. When the thickness t2 of the second resonant layer RS2 in the third direction DR3 is formed to be smaller than the thickness t3 of the third resonant layer RS3 in the third direction DR3, the depth D2 of the second opening OP2 in the third direction DR3 may be greater than a depth D3 of the third opening OP3 in the third direction DR3. In an example, the depth D3 of the third opening OP3 in the third direction DR3 may be substantially equal to the thickness of the first layer L1 in the third direction DR3.

In some embodiments, a separator SPR may be provided in a boundary area BDA between sub-pixels SP1, SP2, and SP3 adjacent to each other. The separator SPR may cause a discontinuity to be formed in the light emitting structure EMS in the boundary area BDA. For example, the light emitting structure EMS may be cut or bent by the separator SPR in the boundary area BDA.

The separator SPR may be provided in or on the pixel defining layer PDL. The pixel defining layer PDL may include one or more trenches TRCH1 and TRCH2 as the separator SPR. In some embodiments, as shown in FIG. 7, the one or more trenches TRCH1 and TRCH2 may penetrate the pixel defining layer PDL, and partially penetrate the via layer VIAL.

In FIGS. 7 to 9, it is illustrated that two trenches TRCH1 and TRCH2 are provided in the boundary area BDA. However, embodiments are not limited thereto. For example, the pixel defining layer PDL may include one trench in the boundary area BDA. Alternatively, the pixel defining layer PDL may include three or more trenches in the boundary area BDA.

Due to first and second trenches TRCH1 and TRCH2, discontinuities such as a first void VD1 and a second void VD2 may be formed in the light emitting structure EMS in the boundary area BDA. Some of a plurality of layers stacked in the light emitting structure EMS may be cut or bent by the first and second voids VD1 and VD2. For example, at least one charge generation layer included in the light emitting structure EMS may be cut by the first and second voids VD1 and VD2. As such, due to the first and second trenches TRCH1 and TRCH2, portions of the light emitting structure EMS, included in the first to third sub-pixels SP1, SP2, and SP3, may be at least partially separated from each other.

In FIG. 7, it is illustrated that the first and second voids VD1 and VD2 are formed in the light emitting structure EMS in the boundary area BDA. However, this is merely illustrative, and embodiments are not limited thereto. For example, a concave-shaped valley may be formed in the light emitting structure EMS in the boundary area BDA. The discontinuities formed in the light emitting structure EMS may be variously suitably changed according to shapes of the first and second trenches TRCH1 and TRCH2.

In some embodiments, the light emitting structure EMS may be formed through a process such as vacuum deposition or inkjet printing. The same materials as the light emitting structure EMS may be located on bottom surfaces adjacent to the via layer VIAL among the first and second trenches TRCH1 and TRCH2.

The separator SPR may be variously suitably modified such that the light emitting structure EMS can have a discontinuity in the boundary area BDA. In some embodiments, inorganic insulating patterns additionally stacked on the pixel defining layer PDL without the first and second trenches TRCH1 and TRCH2 may be provided in the boundary area BDA. A width of an inorganic insulating pattern at an uppermost portion among the additionally stacked inorganic insulating patterns may be greater than a width of an inorganic insulating pattern disposed immediately under the inorganic insulating pattern at the uppermost portion. For example, in the boundary area BDA, first to third inorganic insulating patterns may be sequentially stacked from the pixel defining layer PDL, and the third inorganic insulating pattern at the uppermost portion may have a width greater than a width of the second inorganic insulating layer. For example, the pixel defining layer PDL may have a section having a “T” shape or an “I” shape in the boundary area BDA. According to the shape of the pixel defining layer PDL, the plurality of layers included in the light emitting structure EMS may be partially cut or bent in the boundary area BDA.

The light emitting structure EMS may be disposed on the anode electrodes AE and/or the pixel defining layer PDL. The light emitting structure EMS may be disposed on the anode electrodes AE exposed by the openings OP of the pixel defining layer PDL. The light emitting structure EMS may fill the openings OP of the pixel defining layer PDL, and may be entirely disposed throughout (e.g., disposed throughout an entirety of) the first to third sub-pixels SP1, SP2, and SP3. As described above, the light emitting structure EMS may be at least partially cut or bent by the separator SPR in the boundary area BDA. Accordingly, in an operation of the display panel DP, a current leaked from each of the first to third sub-pixels SP1, SP2, and SP3 to a sub-pixel adjacent thereto through layers included in the light emitting structure EMS can be reduced or minimized. Thus, first to third light emitting elements LD1, LD2, and LD3 can operate with relatively high reliability.

The cathode electrode CE may be disposed over the light emitting structure EMS. The cathode electrode CE may be commonly provided in the first to third sub-pixels SP1, SP2, and SP3. The cathode electrode CE may serve as a half mirror which may allow light emitted from the light emitting structure EMS to be partially transmitted therethrough and to be partially reflected therefrom.

The first anode electrode AE1, a portion of the light emitting structure EMS, which overlaps with the first anode electrode AE1, and a portion of the cathode electrode CE, which overlaps with the first anode electrode AE1, may constitute the first light emitting element LD1. The second anode electrode AE2, a portion of the light emitting structure EMS, which overlaps with the second anode electrode AE2, and a portion of the cathode electrode CE, which overlaps with the second anode electrode AE2, may constitute the second light emitting element LD2. The third anode electrode AE3, a portion of the light emitting structure EMS, which overlaps with the third anode electrode AE3, and a portion of the cathode electrode CE, which overlaps with the third anode electrode AE3, may constitute the third light emitting element LD3.

An encapsulation layer TFE may be disposed on the cathode electrode CE. The encapsulation layer TFE may prevent oxygen and/or moisture from infiltrating into the light emitting element layer LDL.

An optical functional layer OFL may be disposed on the encapsulation layer TFE. In some embodiments, the optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting lower layers including the encapsulation layer TFE.

The optical functional layer OFL may include a color filter layer CFL and a lens array LA. The color filter layer CFL may include first to third color filters CF1, CF2, and CF3 respectively corresponding to the first to third sub-pixels SP1, SP2, and SP3.

The first to third color filters CF1, CF2, and CF3 may allow lights having different wavelength ranges to pass therethrough. For example, the first to third color filters CF1, CF2, and CF3 may allow light red, green, and blue colors to pass therethrough, respectively.

In some embodiments, the first to third color filters CF1, CF2, and CF3 may partially overlap with each other in the boundary area BDA. In other embodiments, the first to third color filters CF1, CF2, and CF3 may be spaced apart from each other, and a black matrix may be provided between the first to third color filters CF1, CF2, and CF3.

The lens array LA may be disposed on the color filter layer CFL. The lens array LA may include first to third lenses LS1, LS2, and LS3 respectively corresponding to the first to third sub-pixels SP1, SP2, and SP3. The first to third lenses LS1, LS2, and LS3 may respectively output lights emitted from the first to third light emitting layers LD1, LD2, and LD3 along intended paths, thereby improving light emission efficiency.

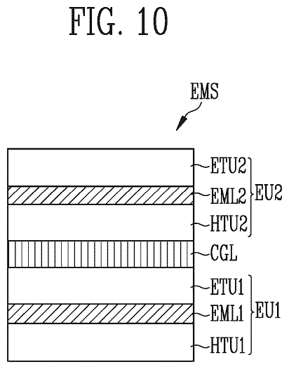

FIG. 10 is a sectional view illustrating a light emitting structure included in any one of the first to third light emitting elements shown in FIG. 7 according to some embodiments of the present disclosure.

Referring to FIG. 10, the light emitting structure EMS may have a tandem structure in which first and second light emitting units EU1 and EU2 are stacked. The light emitting structure EMS may be configured substantially identically in each of the first to third light emitting elements LD1, LD2, and LD3 shown in FIG. 7.

Each of the first and second light emitting units EU1 and EU2 may include at least one light emitting layer generating light according to an applied current. The first light emitting unit EU1 may include a first light emitting layer EML1, a first electron transport unit ETU1, and a first hole transport unit HTU1. The first light emitting layer EML1 may be disposed between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be disposed between the second electron transport unit ETU2 and the second hole transport unit HTU2.

Each of the first and second hole transport units HTU1 and HTU2 may include at least one of a hole injection layer and a hole transport layer. Each of the first and second hole transport units HTU1 and HTU2 may further include a hole buffer layer, an electron blocking layer, and the like, if desired. The first and second hole transport units HTU1 and HTU2 may have the same or substantially the same configuration or have different configurations.

Each of the first and second electron transport units ETU1 and ETU2 may include at least one of an electron injection layer and an electron transport layer. Each of the first and second electron transport units ETU1 and ETU2 may further include an electron buffer layer, a hole blocking layer, and the like, if desired. The first and second electron transport units ETU1 and ETU2 may have the same or substantially the same configuration or have different configurations.

A connection layer, which may be provided in the form of a charge generation layer CGL, may be disposed between the first light emitting unit EU1 and the second light emitting unit EU2 to connect the first light emitting unit EU1 and the second light emitting unit EU2 to each other. In some embodiments, the charge generation layer CGL may have a stacked structure of a p-dopant layer and an n-dopant layer. For example, the p-dopant layer may include a p-type dopant such as HAT-CN, TCNQ, or NDP-9, and the n-dopant layer may include an alkali metal, an alkali earth metal, a lanthanide-based metal, or any combination thereof. However, embodiments are not limited thereto.

In some embodiments, the first light emitting layer EML1 and the second light emitting layer EML2 may generate lights of different colors. Lights respectively emitted from the first light emitting layer EML1 and the second light emitting layer EML2 may be mixed together, to be viewed as white light. For example, the first light emitting layer EML1 may generate light of a blue color, and the second light emitting layer EML2 may generate light of a yellow color. In some embodiments, the second light emitting layer EML2 may include a structure in which a first sub-light emitting layer configured to generate light of a red color and a second sub-light emitting layer configured to generate light of a green color are stacked. The light of the red color and the light of the green color may be mixed together to provide the light of the yellow color. An intermediate layer configured to perform a function of transporting holes and/or a function of blocking transportation of electrodes may be further disposed between the first and second sub-light emitting layers.

In other embodiments, the first light emitting layer EML1 and the second light emitting layer EML2 may generate light of the same or substantially the same color.

The light emitting structure EMS may be formed through a process such as vacuum deposition or inkjet printing, but embodiments are not limited thereto.

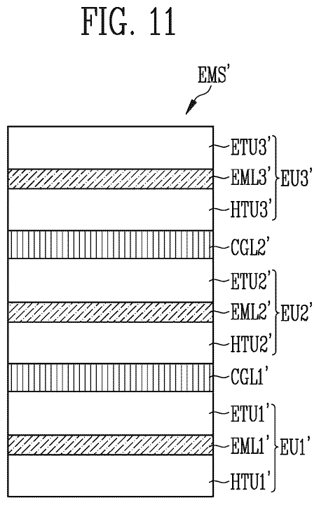

FIG. 11 is a sectional view illustrating another embodiment of the light emitting structure included in the one of the first to third light emitting elements shown in FIG. 7.

Referring to FIG. 11, a light emitting structure EMS′ may a tandem structure in which first to third light emitting units EU1′, EU2′, and EU3′ are stacked. The light emitting structure EMS′ may be configured substantially identically in each of the first to third light emitting elements LD1, LD2, and LD3 shown in FIG. 7.

Each of the first to third light emitting units EU1′, EU2′, and EU3′ may include a light emitting layer generating light according to an applied current. The first light emitting unit EU1′ may include a first light emitting layer EML1′, a first electron transport unit ETU1′ and a first hole transport unit HTU1′. The first light emitting layer EML1′ may be disposed between the first electron transport unit ETU1′ and the first hole transport unit HTU1′. The second light emitting unit EU2′ may include a second light emitting layer EML2′, a second electron transport unit ETU2′, and a second hole transport unit HTU2′. The second light emitting layer EML2′ may be disposed between the second electron transport unit ETU2′ and the second hole transport unit HTU2′. The third light emitting unit EU3′ may include a third light emitting layer EML3′, a third electron transport unit ETU3′, and a third hole transport unit HTU3′. The third light emitting layer EML3′ may be disposed between the third electron transport unit ETU3′ and the third hole transport unit HTU3′.

Each of the first to third hole transport units HTU1′, HTU2′, and HTU3′ may include at least one of a hole injection layer and a hole transport layer, and further include a hole buffer layer, and an electron blocking layer, and the like, if desired. The first to third hole transport units HTU1′, HTU2′, and HTU3′ may have the same or substantially the same configuration or have different configurations.

Each of the first to third electron transport units ETU1′, ETU2′, and ETU3′ may include at least one of an electron injection layer and an electron transport layer, and further include an electron buffer layer, a hole blocking layer, and the like, if desired. The first to third electron transport units ETU1′, ETU2′, and ETU3′ may have the same or substantially the same configuration or have different configurations.

A first charge generation layer CGL1′ may be disposed between the first light emitting unit EU1′ and the second light emitting unit EU2′. A second charge generation layer CGL2′ may be disposed between the second light emitting unit EU2′ and the third light emitting unit EU3′.

In some embodiments, the first to third light emitting layers EML1′, EML2′, and EML3′ may generate lights of different colors. Lights respectively emitted from the first to third light emitting layers EML1′, EML2′, and EML3′ may be mixed to be viewed as white light. For example, the first light emitting layer EML1′ may generate light of a blue color, the second light emitting layer EML2′ may generate light of a green color, and the third light emitting layer EML3′ may generate light of a red color.

In other embodiments, at least two light emitting layers among the first to third light emitting layers EML1′, EML2′, and EML3′ may generate light of the same or substantially the same color.

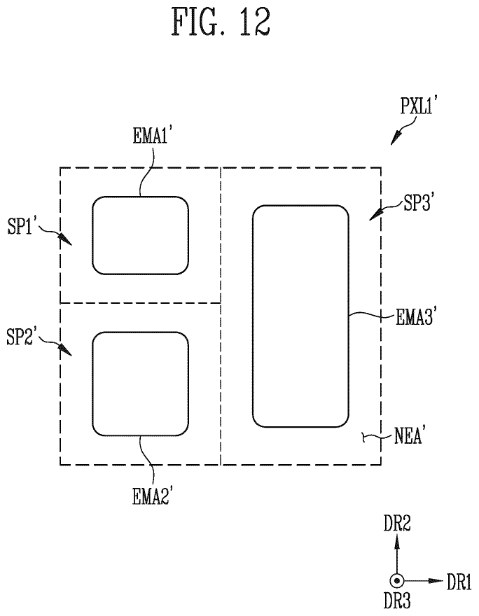

Unlike as shown in FIGS. 11 and 12, the light emitting structure EMS shown in FIG. 7 may include one light emitting unit in each of the first to third light emitting elements LD1, LD2, and LD3. The light emitting unit included in each of the first to third light emitting elements LD1, LD2, and LD3 may be configured to emit lights of different colors. For example, the light emitting unit of the first light emitting element LD1 may emit light of a red color, the light emitting unit of the second light emitting element LD2 may emit light of a green color, and the light emitting unit of the third light emitting element LD3 may emit light of a blue color. Unlike as shown in FIG. 7, light emitting units of the first to third sub-pixels SP1, SP2, and SP3 may be separated from each other, and each of the light emitting units may be disposed in the opening OP of the pixel defining layer PDL. At least some of the color filters CF1, CF2, and CF3 may be omitted.

FIG. 12 is a plan view illustrating one of the pixels shown in FIG. 5 according to some other embodiments of the present disclosure.

Referring to FIG. 12, a first pixel PXL1′ may include first to third sub-pixels SP1′, SP2′, and SP3′.

The first sub-pixel SP1′ may include a first emission area EMA1′ and a non-emission area NEA′ at the periphery of the first emission area EMA1′. The second sub-pixel SP2′ may include a second emission area EMA2′ and the non-emission area NEA′ at the periphery of the second emission area EMA2′. The third sub-pixel SP3′ may include a third emission area EMA3′ and the non-emission area NEA′ at the periphery of the third emission area EMA3′.

The first sub-pixel SP1′ and the second sub-pixel SP2′ may be arranged in the second direction DR2. The third sub-pixel SP3′ may be disposed in the first direction DR1 with respect to each of the first and second sub-pixels SP1′ and SP2′. The second sub-pixel SP2′ may have an area greater than an area of the

first sub-pixel SP1′, and the third sub-pixel SP3′ may have an area greater than the area of the second sub-pixel SP2′. The second emission area EMA2′ may have an area greater than an area of the first emission area EMA1′, and the third emission area EMA3′ may have an area greater than the area of the second emission area EMA2′. However, embodiments are not limited thereto. For example, the first and second sub-pixels SP1′ and SP2′ may substantially have the same area, and the third sub-pixel SP3′ may have an area greater than the area of each of the first and second sub-pixels SP1′ and SP2′. As such, the areas of the first to third sub-pixels SP1′, SP2′, and SP3′ may be variously modified in some embodiments.

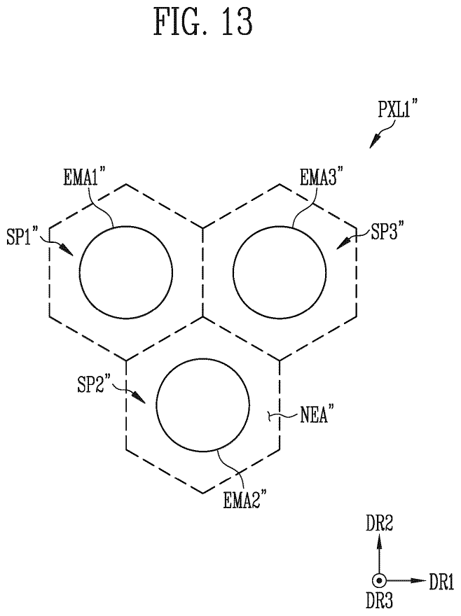

FIG. 13 is a plan view illustrating one of the pixels shown in FIG. 5 according to still some other embodiments.

Referring to FIG. 13, a first sub-pixel SP1″ may include a first emission area EMA1″ and a non-emission area NEA″ at the periphery of the first emission area EMA1″. A second sub-pixel SP2″ may include a second emission area EMA2″ and the non-emission area NEA″ at the periphery of the second emission area EMA2″. A third sub-pixel SP3″ may include a third emission area EMA3″ and the non-emission area NEA″ at the periphery of the third emission area EMA3″.

The first to third sub-pixels SP1″, SP2″, and SP3″ may have polygonal shapes when viewed in the third direction DR3. For example, the shapes of the first to third sub-pixels SP1″, SP2″, and SP3″ may be hexagonal shapes.

The first to third emission areas EMA1″, EMA2″, and EMA3″ may have circular shapes when viewed in the third direction DR3. However, embodiments are not limited thereto. For example, each of the first to third emission areas EMA1″, EMA2″, and EMA3″ may have a polygonal shape.

The first and third sub-pixels SP1″ and SP3″ may be arranged in the first direction DR1. The second sub-pixel SP2″ may be disposed in a direction (or diagonal direction) inclined by an acute angle, based on the second direction DR2, with respect to the first sub-pixel SP1″.

The arrangements of the sub-pixels, which are shown in FIGS. 6, 12, and 13, are merely illustrative, and embodiments are not limited thereto. Each pixel may include two or more sub-pixels, and the sub-pixels may be arranged in various manners. Each of the sub-pixels may have various shapes, and an emission area EMA of the sub-pixel may have various shapes.

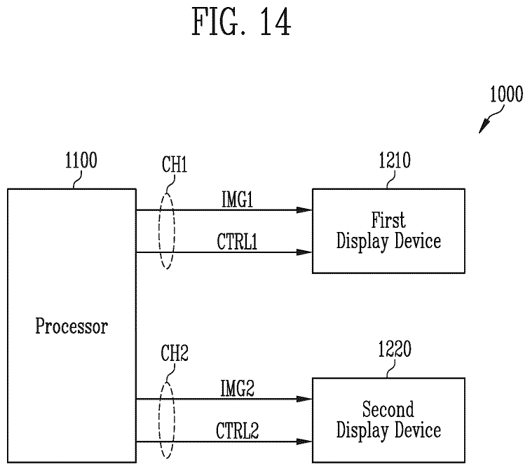

FIG. 14 is a block diagram illustrating a display system according to some embodiments of the present disclosure.

Referring to FIG. 14, a display system 1000 may include a processor 1100 and one or more display devices 1210 and 1220.

The processor 1100 may perform various tasks and various calculations. In some embodiments, the processor 1100 may include an Application Processor (AP), a Graphics Processing Unit (GPU), a microprocessor, a Central Processing Unit (CPU), and the like. The processor 1100 may be connected to other components of the display system 1000 through a bus system to control the components of the display system 1000.

In FIG. 14, it is illustrated that the display system 1000 includes first and second display devices 1210 and 1220. The processor 1100 may be connected to the first display device 1210 through a first channel CH1, and be connected to the second display device 1220 through a second channel CH2.

Through the first channel CH1, the processor 1100 may transmit first image data IMG1 and a first control signal CTRL1 to the first display device 1210. The first display device 1210 may display an image, based on the first image data IMG1 and the first control signal CTRL1. The first display device 1210 may be configured substantially identically to the display device 100 described with reference to FIG. 1. The first image data IMG1 and the first control signal CTRL1 may be respectively provided as the input image data IMG and the control signal CTRL, which are shown in FIG. 1.

Through the second channel CH2, the processor 1100 may transmit second image data IMG2 and a second control signal CTRL2 to the second display device 1220. The second display device 1220 may display an image, based on the second image data IMG2 and the second control signal CTRL2. The second display device 1220 may be configured substantially identically to the display device 100 described with reference to FIG. 1. The second image data IMG2 and the second control signal CTRL2 may be respectively provided as the image data IMG and the control signal CTRL, which are shown in FIG. 1.

The display system 1000 may include a computing system for providing an image display function, such as a portable computer, a mobile phone, a smartphone, a tablet personal computer (PC), a smart watch, a watch phone, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

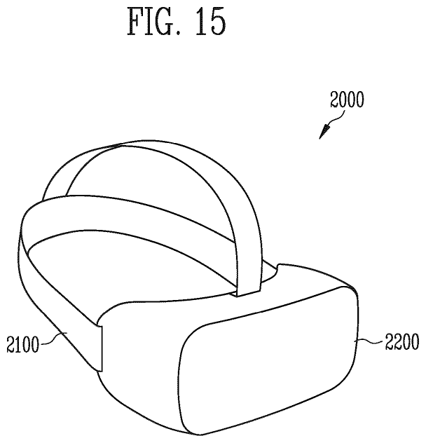

FIG. 15 is a perspective view illustrating an application example of the display system shown in FIG. 14 according to some embodiments of the present disclosure.

Referring to FIG. 15, the display system 1000 shown in FIG. 14 may be applied to a head mounted display device 2000. The head mounted display device 2000 may be a wearable electronic device which can be worn on a head of a user.

The head mounted display device 2000 may include a head mounting band 2100 and a display device accommodating case 2200. The head mounting band 2100 may be connected to the display device accommodating case 2200. The head mounting band 2100 may include a horizontal band and/or a vertical band, used to fix the head mounted display device 2000 to the head of the user. The horizontal band may be configured to surround a side portion of the head of the user, and the vertical band may be configured to surround an upper portion of the head of the user. However, embodiments are not limited thereto. For example, the head mounting band 2100 may be implemented in the form of a glasses frame, a helmet, or the like.

The display device accommodating case 2200 may accommodate the first and second display devices 1210 and 1220 shown in FIG. 14. The display device accommodating case 2200 may further accommodate the processor 1100 shown in FIG. 14.

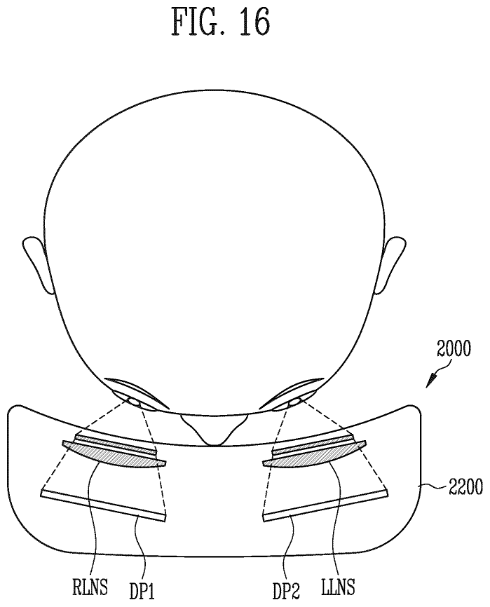

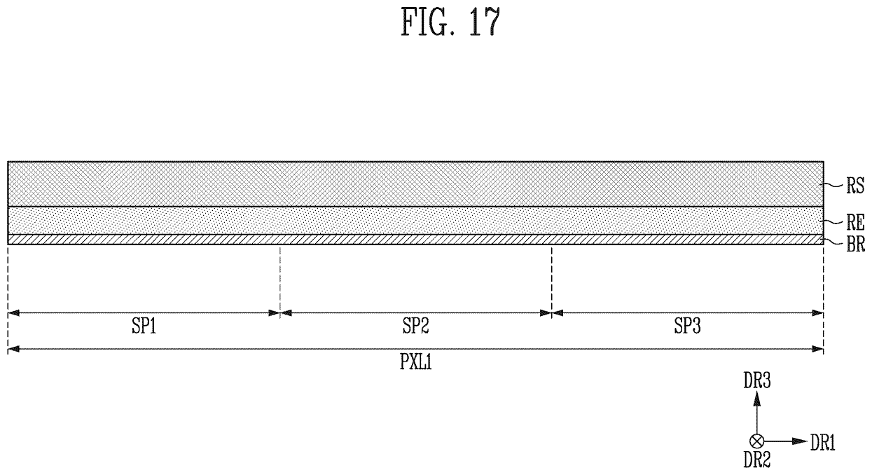

FIG. 16 is a view illustrating a head-mounted display device shown in FIG. 14, which is worn by a user according to some embodiments of the present disclosure.

Referring to FIG. 16, a first display panel DP1 of the first display device 1210 and a second display panel DP2 of the second display device 1220 may be disposed in the head mounted display device 2000. The head mounted display device 2000 may further include one or more lenses LLNS and RLNS.

In the display device accommodating case 2200, a right-eye lens RLNS may be disposed between the first display panel DP1 and a right eye of the user. In the display device accommodating case 2200, a left-eye lens LLNS may be disposed between the second display panel DP2 and a left eye of the user.

An image output from the first display panel DP1 may be viewed by the right eye of the user through the right-eye lens RLNS. The right-eye lens RLNS may refract light emitted from the first display panel DP1 to face the right eye of the user. The right-eye lens RLNS may perform an optical function for adjusting a viewing distance between the first display panel DP1 and the right eye of the user.

An image output from the second display panel DP2 may be viewed by the left eye of the user through the left-eye lens LLNS. The left-eye lens LLNS may refract light emitted from the second display panel DP2 to face the left eye of the user. The left-eye lens LLNS may perform an optical function for adjusting a viewing distance between the second display panel DP2 and the left eye of the user.

In some embodiments, each of the right-eye lens RLNS and the left-eye lens LLNS may include an optical lens having a pancake-shaped section. In some embodiments, each of the right-eye lens RLNS and the left-eye lens LLNS may include a multi-channel lens including sub-areas having different optical characteristics. Each display panel may output images respectively corresponding to the sub-areas of the multi-channel lens, and the output images may be viewed by the user while respectively passing through corresponding sub-areas.

A method of manufacturing the display device in accordance with the above-described embodiment will be described below.

FIGS. 17 to 24 are sectional views illustrating process steps of a method of manufacturing a display device according to some embodiments of the present disclosure. FIGS. 17 to 24 are sectional views illustrating a method of manufacturing the display device shown in FIGS. 1 to 8. For convenience of description, configurations shown in FIGS. 17 to 24 are briefly illustrated, and detailed reference numerals are omitted.

Referring to FIG. 17, first, a barrier layer BR, a reflective electrode RE, and/or a resonant layer RS may be formed in first to third sub-pixels SP1, SP2, and SP3. The barrier layer BR, the reflective electrode RE, and/or the resonant layer RS may be formed on the substrate SUB, the pixel circuit layer PCL, and/or the via layer VIAL, which are described with reference to FIG. 7. The barrier layer BR may be formed on the via layer VIAL. The reflective electrode RE may be formed on the barrier layer BR. The resonant layer RS may be formed on the reflective electrode RE.

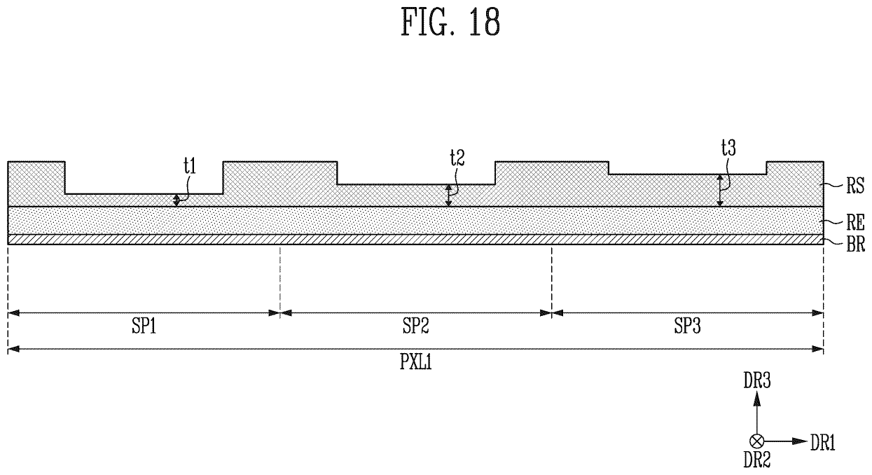

Referring to FIG. 18, subsequently, the resonant layer RS of the first to third sub-pixels SP1, SP2, and SP3 may be etched to different thicknesses. For example, a thickness t1 of the resonant layer RS of the first sub-pixel SP1 in the third direction DR3 may be smaller than a thickness t2 of the resonant layer RS of the second sub-pixel SP2 in the third direction DR3. Accordingly, the first sub-pixel SP1 may have a resonance distance shorter than a resonance distance of the second sub-pixel SP2. The thickness t2 of the resonant layer RS of the second sub-pixel SP2 in the third direction DR3 may be smaller than a thickness t3 of the resonant layer RS of the third sub-pixel SP3 in the third direction DR3. Accordingly, the second sub-pixel SP2 may have a resonance distance shorter than a resonance distance of the third sub-pixel SP3. As such, the resonance distance of each of the first to third sub-pixels SP1, SP2, and SP3 is adjusted by adjusting the thickness of the resonant layer RS of each of the first to third sub-pixels SP1, SP2, and SP3, so that the luminance of the display device can be improved, which has been described above.

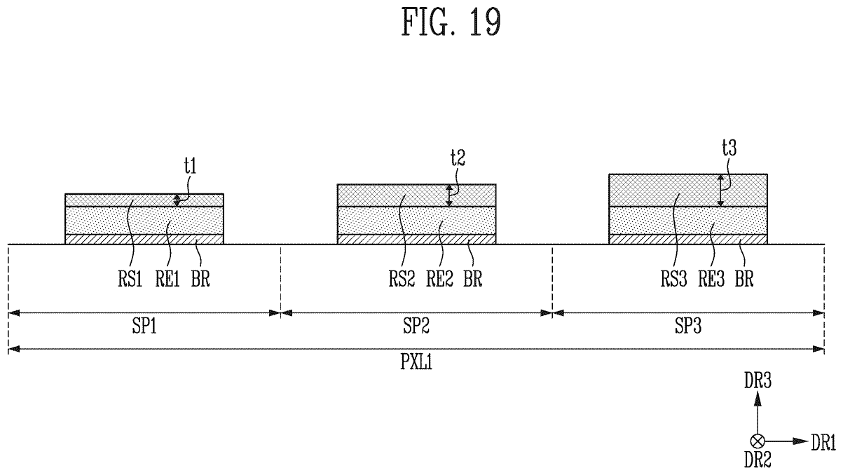

Referring to FIG. 19, subsequently, the barrier layer BR, the reflective electrode RE, and/or the resonant layer RS may be patterned. Accordingly, barrier layers BR, first to third reflective electrodes RE1, RE2, and RE3, and/or first to third resonant layers RS1, RS2, and RS3 may be formed in the first to third sub-pixels SP1, SP2, and SP3, respectively.

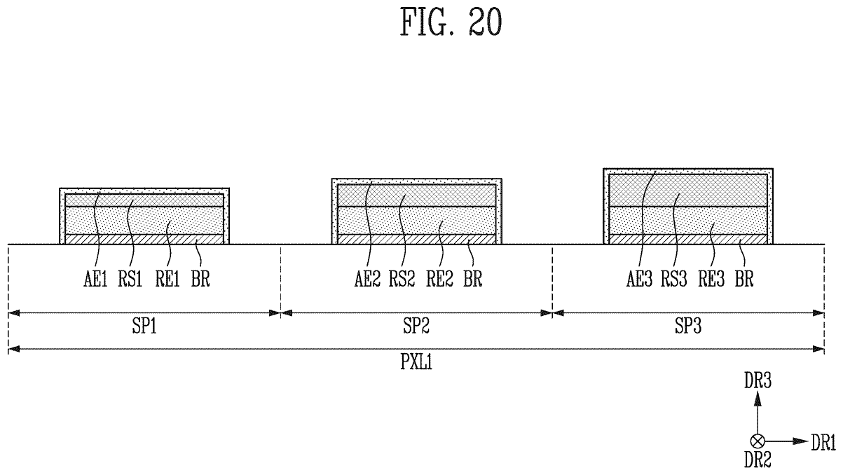

Referring to FIG. 20, subsequently, first to third anode electrodes AE1, AE2, and AE3 may be formed on the barrier layers BR, the first to third reflective electrodes RE1, RE2, and RE3, and/or the first to third resonant layers RS1, RS2, and RS3, respectively.

The first to third anode electrodes AE1, AE2, and AE3 may cover side surfaces and top surfaces of the first to third resonant layers RS1, RS2, and RS3, respectively. The first to third anode electrodes AE1, AE2, and AE3 may be formed directly on the side surfaces and the top surfaces of the first to third resonant layers RS1, RS2, and RS3, respectively. The first to third anode electrodes AE1, AE2, and AE3 may be in contact with the side surfaces and the top surfaces of the first to third resonant layers RS1, RS2, and RS3, respectively.

The first to third anode electrodes AE1, AE2, and AE3 may cover side surfaces of the first to third reflective electrodes RE1, RE2, and RE3, respectively. The first to third anode electrodes AE1, AE2, and AE3 may be formed directly on the side surfaces of the first to third reflective electrodes RE1, RE2, and RE3, respectively. The first to third anode electrodes AE1, AE2, and AE3 may be in contact with the side surfaces of the first to third reflective electrodes RE1, RE2, and RE3, respectively.

The first to third anode electrodes AE1, AE2, and AE3 may cover side surfaces of the barrier layers BR, respectively. The first to third anode electrodes AE1, AE2, and AE3 may be formed directly on the side surfaces of the barrier layers BR, respectively. The first to third anode electrodes AE1, AE2, and AE3 may be in contact with the side surfaces of the barrier layers BR, respectively.

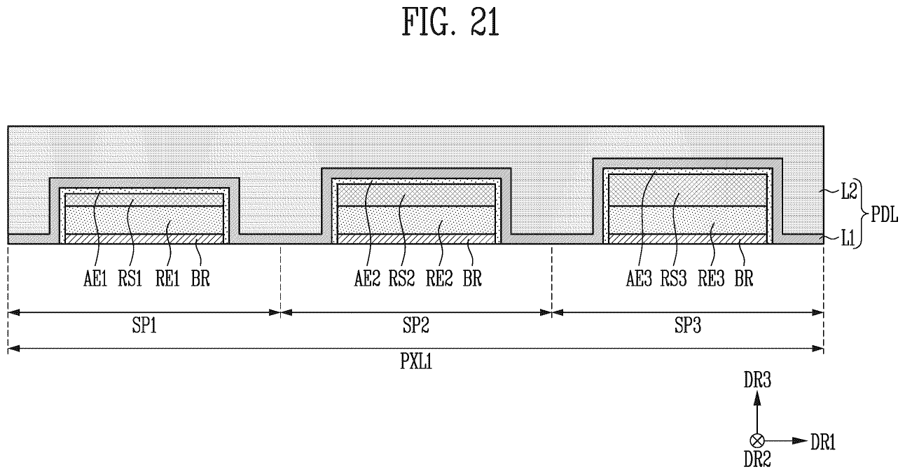

Referring to FIG. 21, subsequently, a pixel defining layer PDL may be formed over the first to third anode electrodes AE1, AE2, and AE3. The pixel defining layer PDL may include a first layer L1 and a second layer L2. The first layer L1 may be formed on the first to third anode electrodes AE1, AE2, and AE3. The second layer L2 may be formed on the first layer L1. A thickness of the second layer L2 in the third direction DR3 may be formed to be greater than a thickness of the first layer L1 in the third direction DR3. The first layer L1 and/or the second layer L2 may be formed of at least one of silicon oxide (SiOₓ) and silicon nitride (SiNₓ). For example, the first layer L1 may be formed of silicon nitride (SiNₓ), and the second layer L2 may be formed of silicon oxide (SiOₓ). However, the present disclosure is not necessarily limited thereto.

Referring to FIG. 22, subsequently, the pixel defining layer PDL may be polished. A top surface of the pixel defining layer PDL may be formed flat through Chemical Mechanical Polish (CMP). The first layer L1 may be serve as an etch stopper in a process of polishing the pixel defining layer PDL. For example, as the second layer L2 is polished in the process of polishing the pixel defining layer PDL, a top surface of the first layer L1 of the third sub-pixel SP3 may be exposed.

Due to thickness differences of the first to third resonant layers RS1, RS2, and RS3, thicknesses of the pixel defining layer PDL on the first to third anode electrodes AE1, AE2, and AE3 may be different from one another. For example, a thickness of the pixel defining layer PDL on the first anode electrode AE1 in the third direction DR3 may be greater than a thickness of the pixel defining layer PDL on the second anode electrode AE2 in the third direction DR3. The thickness of the pixel defining layer PDL on the second anode electrode AE2 in the third direction DR3 may be greater than a thickness of the pixel defining layer PDL on the third anode electrode AE3 in the third direction DR3.

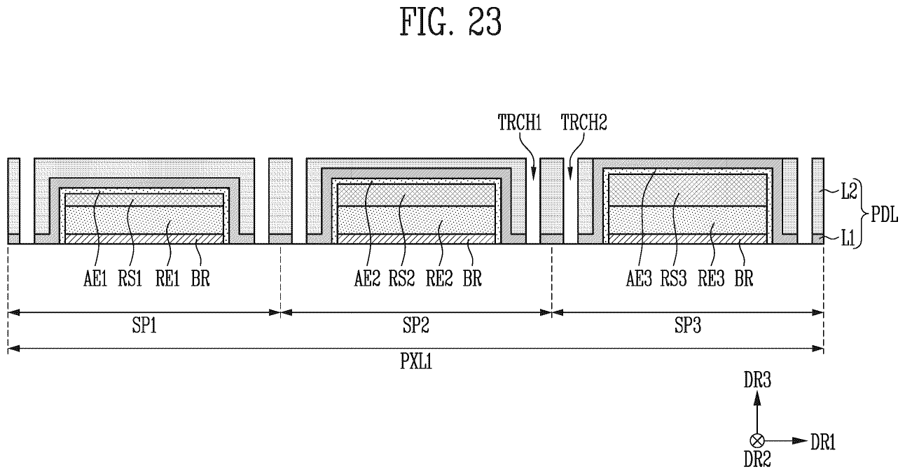

Referring to FIG. 23, subsequently, trenches TRCH1 and TRCH2 may be formed in the pixel defining layer PDL. The trenches TRCH1 and TRCH2 may be formed between the first to third sub-pixels SP1, SP2, and SP3. Due to the trenches TRCH1 and TRCH2, portions of a light emitting structure EMS included in the first to third sub-pixels SP1, SP2, and SP3 may be at least partially separated from each other. Accordingly, a current leaked from each of the first to third sub-pixels SP1, SP2, and SP3 to a sub-pixel adjacent thereto through layers included in the light emitting structure EMS can be reduced or minimized, which has been described above.

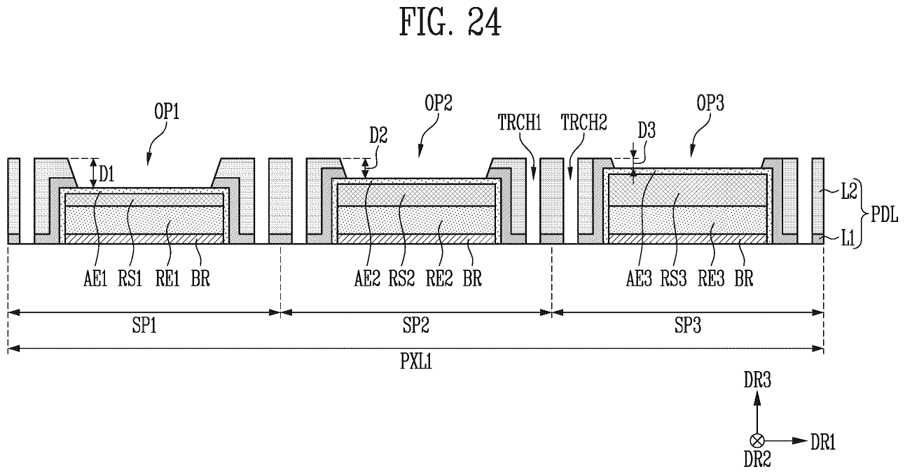

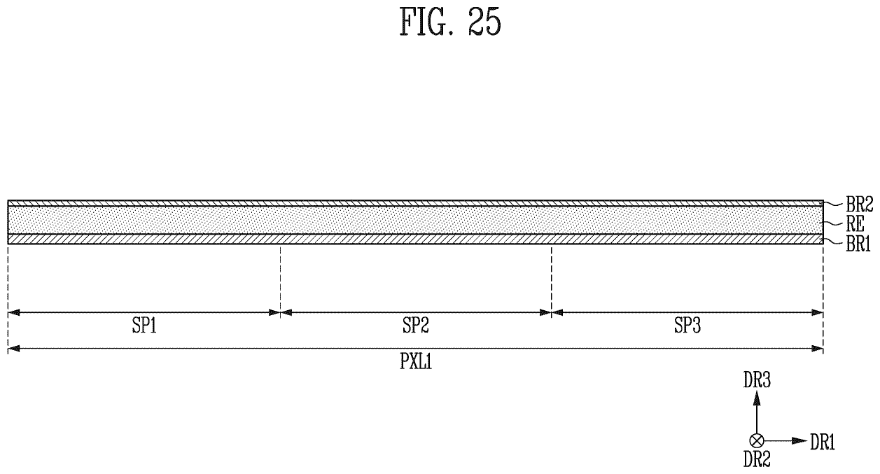

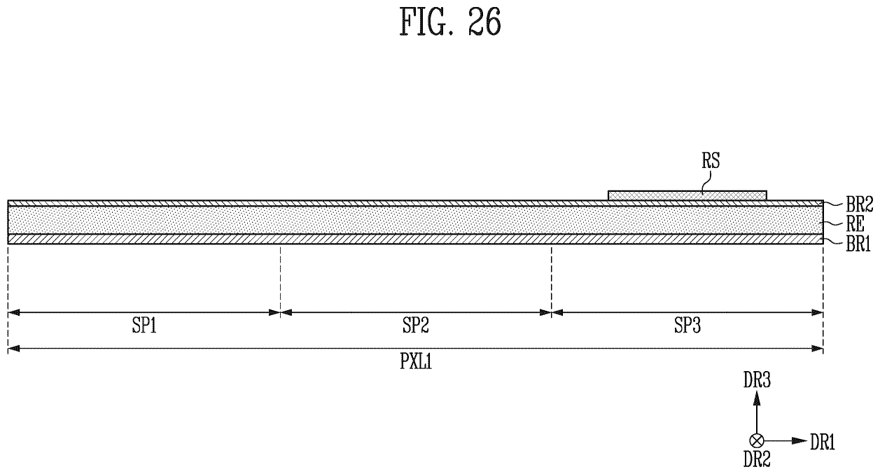

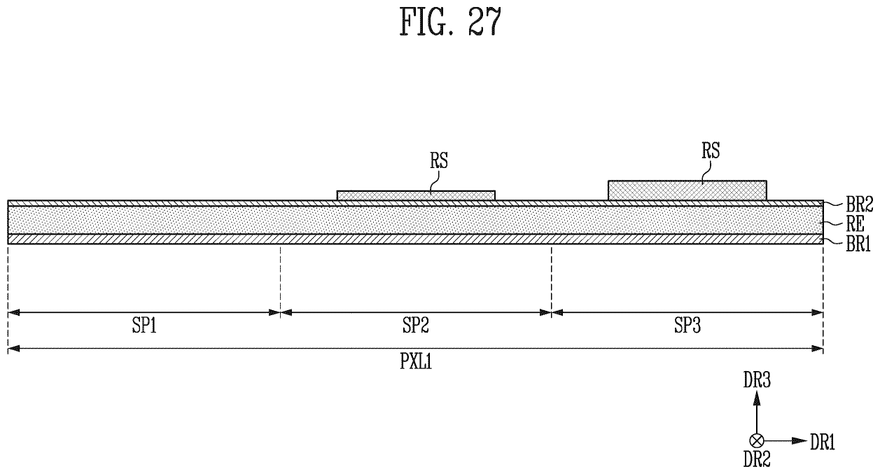

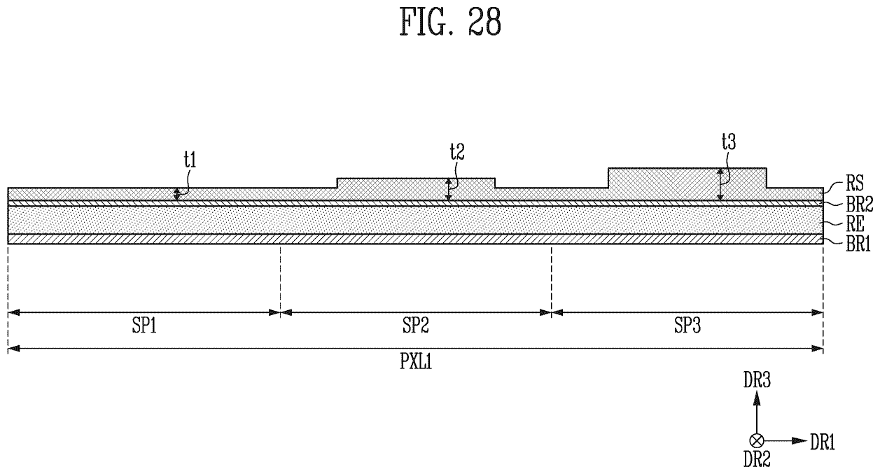

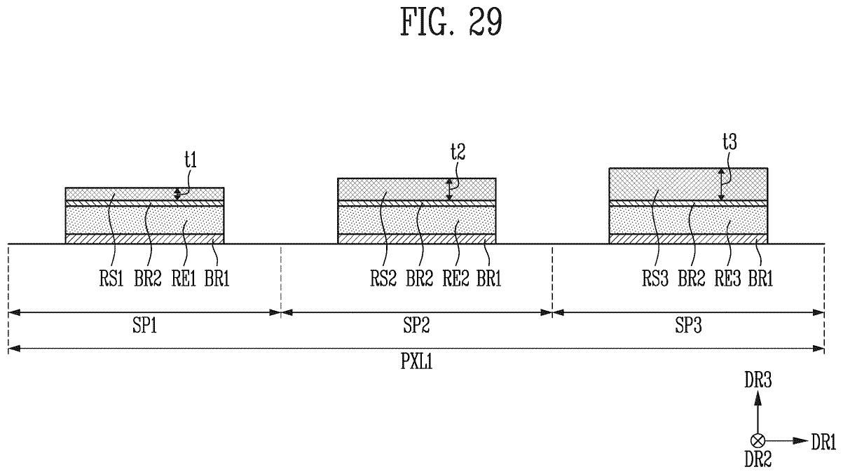

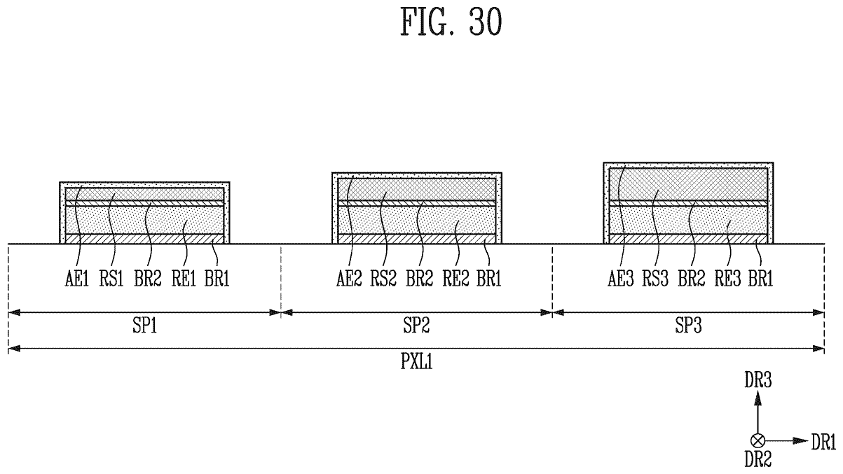

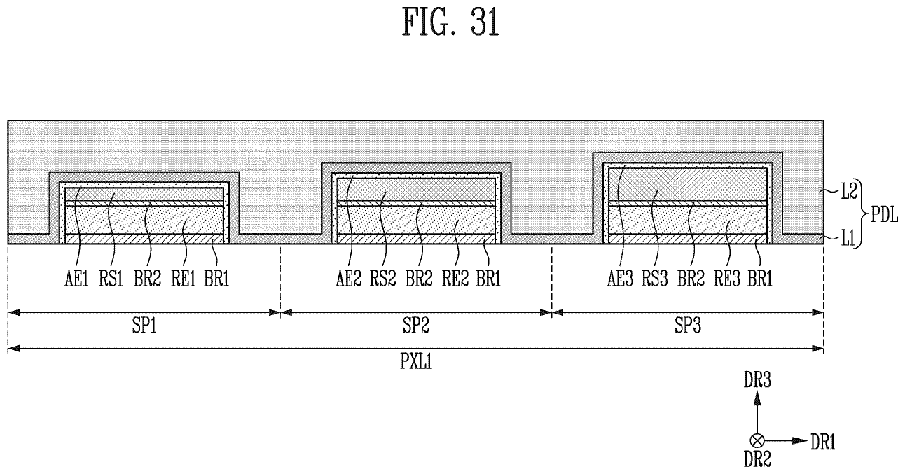

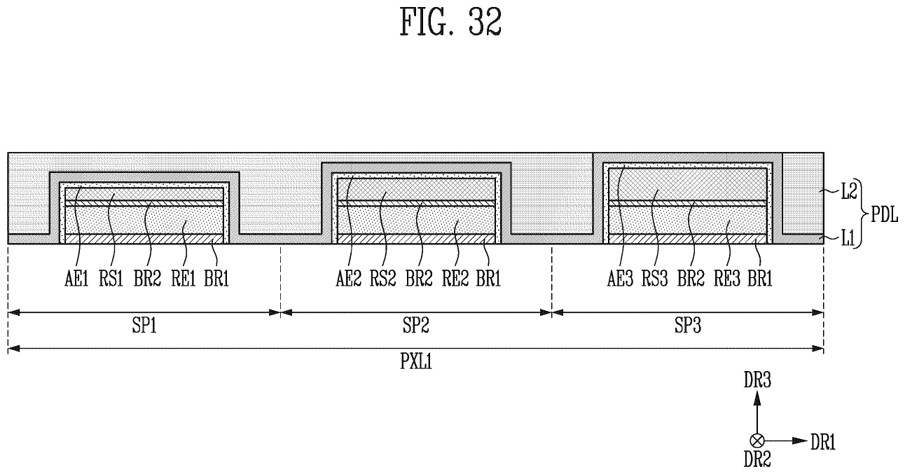

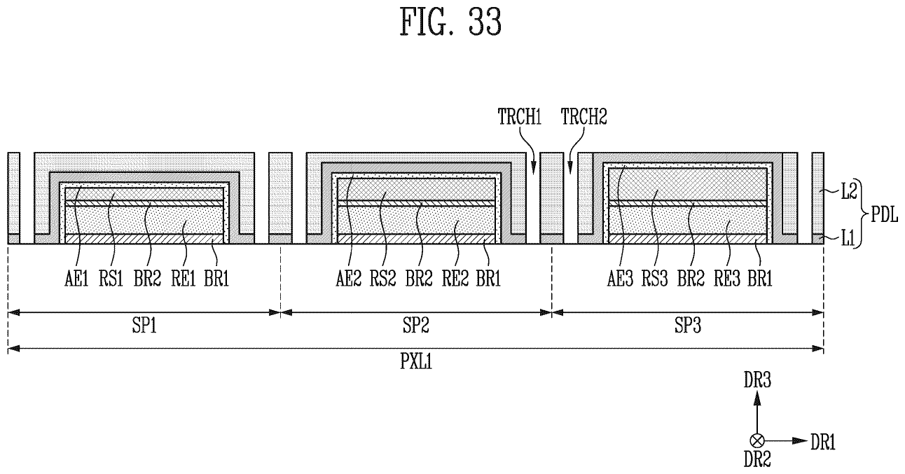

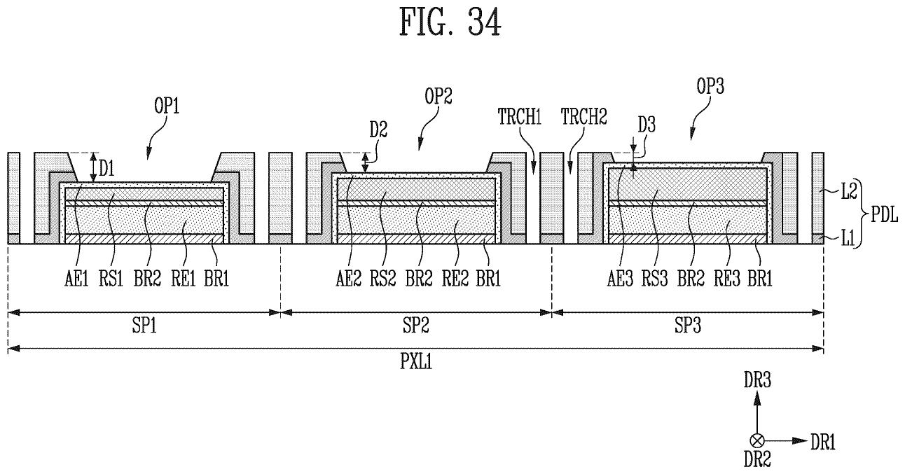

Referring to FIG. 24, subsequently, first to third openings OP1, OP2, and OP3 may be formed in the pixel defining layer PDL of the first to third sub-pixels SP1, SP2, and SP3. The first to third openings OP1, OP2, and OP3 may expose the first to third anode electrodes AE1, AE2, and AE3, respectively.

Due to the thickness differences of the first to third resonant layers RS1, RS2, and RS3, the first to third openings OP1, OP2, and OP3 of the pixel defining layer PDL may have different depths. For example, when the thickness t1 of the first resonant layer RS1 in the third direction DR3 is formed smaller than the thickness t2 of the second resonant layer RS2 in the third direction DR3, a depth D1 of the first opening OP1 in the third direction DR3 may be greater than a depth D2 of the second opening OP2 in the third direction DR3. When the thickness t2 of the second resonant layer RS2 in the third direction DR3 is formed smaller than the thickness t3 of the third resonant layer RS3 in the third direction DR3, the depth D2 of the second opening OP2 in the third direction DR3 may be greater than a depth D3 of the third opening OP3 in the third direction DR3. The depth D3 of the third opening OP3 in the third direction DR3 may be substantially equal to the thickness of the first layer L1 in the third direction DR3.

Subsequently, a light emitting structure EMS and the like may be formed on the first to third anode electrodes AE1, AE2, and AE3 and the pixel defining layer PDL as described with reference to FIG. 7, thereby completing the display device.

Hereinafter, another embodiment of the present disclosure will be described. In the following embodiment, components identical to those which have already been described are designated by like reference numerals, and overlapping descriptions will be omitted or simplified.

FIGS. 25 to 34 are sectional views illustrating process steps of a method of manufacturing a display device according to some embodiments of the present disclosure. FIGS. 25 to 34 are sectional views illustrating a method of manufacturing the display device shown in FIG. 9. For convenience of description, configurations shown in FIGS. 25 to 34 are briefly illustrated, and detailed reference numerals are omitted.

Referring to FIG. 25, first, a first barrier layer BR1, a reflective electrode RE, and/or a second barrier layer BR2 may be formed in first to third sub-pixels SP1, SP2, and SP3. The first barrier layer BR1, the reflective electrode RE, and/or the second barrier layer BR2 may be formed on the substrate SUB, the pixel circuit layer PCL, and the via layer VIAL, which are described with reference to FIG. 8. The first barrier layer BR1 may be formed on the via layer VIAL. The reflective electrode RE may be formed on the first barrier layer BR1. The second barrier layer BR2 may be formed on the reflective electrode RE. A thickness of the second barrier BR2 may be formed to be smaller than a thickness of the first barrier BR1, but the present disclosure is not necessarily limited thereto.

Referring to FIG. 26, subsequently, a resonant layer RS may be primarily formed in the third sub-pixel SP3. The resonant layer RS may be partially deposited on the second barrier BR2 in the third sub-pixel SP3.

Referring to FIG. 27, subsequently, a resonant layer RS may be secondarily formed in the second sub-pixels SP2 and the third sub-pixel SP3. The resonant layer RS may be partially deposited on the second barrier layer BR2 in the second sub-pixels SP2 and the third sub-pixel SP3. A thickness of the resonant layer RS formed in the second sub-pixel SP2 in the third direction DR3 may be smaller than a thickness of the resonant layer RS formed in the third sub-pixel SP3 in the third direction DR3.

Referring to FIG. 28, subsequently, a resonant layer RS may be tertiarily formed in the first to third sub-pixels SP1, SP2, and SP3. The resonant layer RS may be entirely deposited on (e.g., deposited on an entirety of) the second barrier layer BR2 in the first to third sub-pixels SP1, SP2, and SP3. As such, as the resonant layers SR are sequentially formed, the resonant layers RS having different thicknesses may be formed in first to third sub-pixels SP1, SP2, and SP3.

A thickness t1 of the resonant layer RS of the first sub-pixel SP1 in the third direction DR3 may be smaller than a thickness t2 of the resonant layer RS of the second sub-pixel SP2 in the third direction DR3. Accordingly, the first sub-pixel SP1 may have a resonance distance shorter than a resonance distance of the second sub-pixel SP2. The thickness t2 of the resonant layer RS of the second sub-pixel SP2 in the third direction DR3 may be smaller than a thickness t3 of the resonant layer RS of the third sub-pixel SP3 in the third direction DR3. Accordingly, the second sub-pixel SP2 may have a resonance distance shorter than a resonance distance of the third sub-pixel SP3. As such, the resonance distance of each of the first to third sub-pixels SP1, SP2, and SP3 is adjusted by adjusting the thickness of the resonant layer RS of each of the first to third sub-pixels SP1, SP2, and SP3, so that the luminance of the display device can be improved, which has been described above.

Referring to FIG. 29, subsequently, the first barrier layer BR1, the reflective electrode RE, the second barrier layer BR2, and/or the resonant layer RS may be patterned. Accordingly, first barrier layers BR1, first to third reflective electrodes RE1, RE2, and RE3, second barrier layers BR2, and/or first to third resonant layers RS1, RS2, and RS3 may be formed in the first to third sub-pixels SP1, SP2, and SP3, respectively.

Referring to FIG. 30, subsequently, first to third anode electrodes AE1, AE2, and AE3 may be formed on the first barrier layers BR1, the first to third reflective electrodes RE1, RE2, and RE3, the second barrier layers BR2, and/or the first to third resonant layers RS1, RS2, and RS3, respectively.

The first to third anode electrodes AE1, AE2, and AE3 may cover side surfaces and top surfaces of the first to third resonant layers RS1, RS2, and RS3, respectively. The first to third anode electrodes AE1, AE2, and AE3 may be formed directly on the side surfaces and the top surfaces of the first to third resonant layers RS1, RS2, and RS3, respectively. The first to third anode electrodes AE1, AE2, and AE3 may be in contact with the side surfaces and the top surfaces of the first to third resonant layers RS1, RS2, and RS3, respectively.

The first to third anode electrodes AE1, AE2, and AE3 may cover side surfaces of the first to third reflective electrodes RE1, RE2, and RE3, respectively. The first to third anode electrodes AE1, AE2, and AE3 may be formed directly on the side surfaces of the first to third reflective electrodes RE1, RE2, and RE3, respectively. The first to third anode electrodes AE1, AE2, and AE3 may be in contact with the side surfaces of the first to third reflective electrodes RE1, RE2, and RE3, respectively.

The first to third anode electrodes AE1, AE2, and AE3 may cover side surfaces of the first and second barrier layers BR1 and BR2, respectively. The first to third anode electrodes AE1, AE2, and AE3 may be formed directly on the side surfaces of the first and second barrier layers BR1 and BR2, respectively. The first to third anode electrodes AE1, AE2, and AE3 may be in contact with the side surfaces of the first and second barrier layers BR1 and BR2, respectively.

Referring to FIG. 31, subsequently, a pixel defining layer PDL may be formed over the first to third anode electrodes AE1, AE2, and AE3. The pixel defining layer PDL may include a first layer L1 and a second layer L2. The first layer L1 may be formed on the first to third anode electrodes AE1, AE2, and AE3. The second layer L2 may be formed on the first layer L1. A thickness of the second layer L2 in the third direction DR3 may be formed to be greater than a thickness of the first layer L1 in the third direction DR3. The first layer L1 and/or the second layer L2 may be formed of at least one of silicon oxide (SiOₓ) and silicon nitride (SiNₓ). For example, the first layer L1 may be formed of silicon nitride (SiNₓ), and the second layer L2 may be formed of silicon oxide (SiOₓ). However, the present disclosure is not necessarily limited thereto.

Referring to FIG. 32, subsequently, the pixel defining layer PDL may be polished. A top surface of the pixel defining layer PDL may be formed flat through Chemical Mechanical Polish (CMP). The first layer L1 may be serve as an etch stopper in a process of polishing the pixel defining layer PDL. For example, as the second layer L2 is polished in the process of polishing the pixel defining layer PDL, a top surface of the first layer L1 of the third sub-pixel SP3 may be exposed.

Due to thickness differences of the first to third resonant layers RS1, RS2, and RS3, thicknesses of the pixel defining layer PDL on the first to third anode electrodes AE1, AE2, and AE3 may be different from one another. For example, a thickness of the pixel defining layer PDL on the first anode electrode AE1 in the third direction DR3 may be greater than a thickness of the pixel defining layer PDL on the second anode electrode AE2 in the third direction DR3. The thickness of the pixel defining layer PDL on the second anode electrode AE2 in the third direction DR3 may be greater than a thickness of the pixel defining layer PDL on the third anode electrode AE3 in the third direction DR3.

Referring to FIG. 33, subsequently, trenches TRCH1 and TRCH2 may be formed in the pixel defining layer PDL. The trenches TRCH1 and TRCH2 may be formed between the first to third sub-pixels SP1, SP2, and SP3. Due to the trenches TRCH1 and TRCH2, portions of a light emitting structure EMS included in the first to third sub-pixels SP1, SP2, and SP3 may be at least partially separated from each other. Accordingly, a current leaked from each of the first to third sub-pixels SP1, SP2, and SP3 to a sub-pixel adjacent thereto through layers included in the light emitting structure EMS can be reduced or minimized, which has been described above.

Referring to FIG. 34, subsequently, first to third openings OP1, OP2, and OP3 may be formed in the pixel defining layer PDL of the first to third sub-pixels SP1, SP2, and SP3. The first to third openings OP1, OP2, and OP3 may expose the first to third anode electrodes AE1, AE2, and AE3, respectively.

Due to the thickness differences of the first to third resonant layers RS1, RS2, and RS3, the first to third openings OP1, OP2, and OP3 of the pixel defining layer PDL may have different depths. For example, when the thickness t1 of the first resonant layer RS1 in the third direction DR3 is formed to be smaller than the thickness t2 of the second resonant layer RS2 in the third direction DR3, a depth D1 of the first opening OP1 in the third direction DR3 may be greater than a depth D2 of the second opening OP2 in the third direction DR3. When the thickness t2 of the second resonant layer RS2 in the third direction DR3 is formed to be smaller than the thickness t3 of the third resonant layer RS3 in the third direction DR3, the depth D2 of the second opening OP2 in the third direction DR3 may be greater than a depth D3 of the third opening OP3 in the third direction DR3. The depth D3 of the third opening OP3 in the third direction DR3 may be substantially equal to the thickness of the first layer L1 in the third direction DR3.

Subsequently, a light emitting structure EMS and the like may be formed on the first to third anode electrodes AE1, AE2, and AE3 and the pixel defining layer PDL as described with reference to FIG. 8, thereby completing the display device.

In accordance with the present disclosure, a resonance distance of each of sub-pixels can be adjusted using resonant layers of the sub-pixels. Accordingly, light in a corresponding wavelength range can be efficiently output in each of the sub-pixels, and thus the luminance of the display device can be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims and their equivalents.

1 what is claimed is:

1. A display device comprising:
first to third sub-pixels,
wherein each of the first to third sub-pixels comprises:
a reflective electrode;
a resonant layer on the reflective electrode;
a first electrode on the resonant layer;
a pixel defining layer positioned over the first electrode, the pixel defining layer having an opening;
a light emitting structure on the first electrode and the pixel defining layer; and
a second electrode on the light emitting structure,
wherein a thickness of the resonant layer of the first sub-pixel is smaller than a thickness of the resonant layer of the second sub-pixel, and
wherein a depth of the opening of the first sub-pixel is greater than a depth of the opening of the second sub-pixel.

2. The display device of claim 1, wherein the first electrode covers a top surface and a side surface of the resonant layer.

3. The display device of claim 1, wherein the first electrode is in contact with a side surface of the reflective electrode.

4. The display device of claim 1, wherein the thickness of the resonant layer of the second sub-pixel is smaller than a thickness of the resonant layer of the third sub-pixel.

5. The display device of claim 1, wherein the depth of the opening of the second sub-pixel is greater than a depth of the opening of the third sub-pixel.

6. The display device of claim 1, wherein the pixel defining layer comprises a first layer on the first electrode and a second layer on the first layer.

7. The display device of claim 6, wherein the depth of the opening of the third sub-pixel is equal to a thickness of the first layer.

8. The display device of claim 6, wherein a thickness of the first layer is smaller than a thickness of the second layer.

9. The display device of claim 1, further comprising a first barrier layer on the bottom of the reflective electrode.

10. The display device of claim 9, further comprising a second barrier layer on the top of the reflective electrode.

11. The display device of claim 10, wherein a thickness of the second barrier layer is smaller than a thickness of the first barrier layer.

12. A method of manufacturing a display device, the method comprising:
forming a reflective electrode in first to third sub-pixels;
forming a resonant layer on the reflective electrode;
patterning the reflective electrode and the resonant layer;
forming a first electrode on the reflective electrode and the resonant layer;
forming a pixel defining layer over the first electrode;
polishing the pixel defining layer;
forming a trench of the pixel defining layer between the first to third sub-pixels;
forming an opening exposing the first electrode in the pixel defining layer; and
forming a light emitting structure on the first electrode exposed by the opening,
wherein the resonant layers of the first to third sub-pixels are formed to have different thicknesses from each other.

13. The method of claim 12, wherein the first electrode is formed directly on a top surface and a side surface of the resonant layer.

14. The method of claim 12, wherein the first electrode is formed directly on a side surface of the reflective electrode.

15. The method of claim 12, wherein a thickness of the resonant layer of the first sub-pixel is formed to be smaller than a thickness of the resonant layer of the second sub-pixel.

16. The method of claim 15, wherein a depth of the opening of the first sub-pixel is formed to be greater than a depth of the opening of the second sub-pixel.

17. The method of claim 12, wherein a thickness of the resonant layer of the second sub-pixel is formed to be smaller than a thickness of the resonant layer of the third sub-pixel.

18. The method of claim 17, wherein a depth of the opening of the second sub-pixel is formed to be greater than a depth of the opening of the third sub-pixel.

19. The method of claim 12, further comprising forming a barrier layer between the reflective electrode and the resonant layer.

20. The method of claim 12, wherein the pixel defining layer comprises a first layer and a second layer formed on the first layer, and
wherein, in the polishing of the pixel defining layer, the second layer is polished such that a top surface of the first layer of the third sub-pixel is exposed.

21. An electronic device comprising:
a processor to provide input image data; and
a display device to display an image based on the input image data, the display device including sub-pixel areas,
wherein the display device comprises:
first to third sub-pixels,
wherein each of the first to third sub-pixels comprises:
a reflective electrode;
a resonant layer on the reflective electrode;
a first electrode on the resonant layer;
a pixel defining layer positioned over the first electrode, the pixel defining layer having an opening;
a light emitting structure on the first electrode and the pixel defining layer; and
a second electrode on the light emitting structure,
wherein a thickness of the resonant layer of the first sub-pixel is smaller than a thickness of the resonant layer of the second sub-pixel, and
wherein a depth of the opening of the first sub-pixel is greater than a depth of the opening of the second sub-pixel.
